(19) United States
(12) Patent Application Publication
(10) Pub. No.: US 2025/0228069 A1
(43) Pub. Date: Jul. 10, 2025

(54) Light-Emitting Device and Display Panel

(71) Applicant: BOE TECHNOLOGY GROUP CO., LTD., Chaoyang District, Beijing (CN)

(72) Inventors: Dan Wang, Beijing (CN); Haiyan Sun, Beijing (CN)

(21) Appl. No.: 18/852,715

(22) PCT Filed: Jun. 20, 2023
(86) PCT No.: PCT/CN2023/101474

§ 371 Date: Sep. 30, 2024

(30) Foreign Application Priority Data
Jul. 6, 2022 (CN) 202210789887.1

(51) Int. Cl. H10K 50/19; H10K 50/155; H10K 50/18

(52) U.S. Cl. CPC H10K 50/19; H10K 50/155; H10K 50/18

(57) ABSTRACT

A light-emitting device includes a first electrode, at least two light-emitting units and a second electrode that are stacked in sequence. The at least two light-emitting units include a first light-emitting unit, and a second light-emitting unit located between the first light-emitting unit and the second electrode. The light-emitting device further includes a charge generation layer located between the first light-emitting unit and the second light-emitting unit. The first light-emitting unit includes a first light-emitting layer; and multiple film layers located on a side of the first light-emitting layer away from the first electrode in the light-emitting device collectively include at least three types of metals.

### CROSS-REFERENCE TO RELATED APPLICATIONS

This application is the United States national phase of International Patent Application No. PCT/CN2023/101474, filed Jun. 20, 2023, and claims priority to Chinese Patent Application No. 202210789887.1, filed Jul. 6, 2022, the disclosures of which are hereby incorporated by reference in their entireties.

### BACKGROUND OF THE INVENTION

### Field of the Invention

The present disclosure relates to the field of display technologies, and in particular, to a light-emitting device and a display panel.

### Description of Related Art

For having various advantages such as self-luminescence, high brightness, high contrast, high response speed, wide viewing angle, simple structure, and flexible display, the organic electroluminescent device (organic light-emitting diode, OLED) is emphasized by enterprises and universities, and has gained rapid development.

Based on this, tandem organic electroluminescent devices (Tandem OLEDs) have emerged in the development of OLEDs. The Tandem OLEDs have the advantage of high brightness. However, Tandem OLEDs in related art have the problem of a large driving voltage.

### SUMMARY OF THE INVENTION

In an aspect, a light-emitting device is provided. The light-emitting device includes a first electrode, at least two light-emitting units and a second electrode that are stacked in sequence. The at least two light-emitting units include a first light-emitting unit, and a second light-emitting unit located between the first light-emitting unit and the second electrode, and the light-emitting device further includes a charge generation layer located between the first light-emitting unit and the second light-emitting unit. The first light-emitting unit includes a first light-emitting layer; and multiple film layers located on a side of the first light-emitting layer away from the first electrode in the light-emitting device collectively include at least three types of metals.

In some embodiments, in the multiple film layers located on the side of the first light-emitting layer away from the first electrode in the light-emitting device, at least three film layers each include metal.

In some embodiments, the at least three film layers include a first film layer, a second film layer and a third film layer that are arranged in sequence along a direction from the first electrode to the second electrode. An absolute value of work function of metal in the third film layer is greater than an absolute value of work function of metal in the second film layer, and the absolute value of the work function of the metal in the third film layer is greater than an absolute value of work function of metal in the first film layer.

In some embodiments, the at least three types of metals include first category metal and second category metal. Work function of the first category metal is less than −3.5 eV, and work function of the second category metal is greater than −3.5 eV.

In some embodiments, the work function of the first category metal is in a range of −5.2 eV to −3.5 eV.

In some embodiments, the second light-emitting unit includes a second light-emitting layer. In the light-emitting device, at least one type of the second category metal is included in a side of the second light-emitting layer proximate to the first electrode, and at least one type of the first category metal and at least one type of the second category metal are included in a side of the second light-emitting layer away from the first electrode.

In some embodiments, the first film layer is located on the side of the second light-emitting layer proximate to the first electrode, and the second film layer and the third film layer are located on the side of the second light-emitting layer away from the first electrode.

In some embodiments, the second film layer and the third film layer are arranged next to each other.

In some embodiments, in the multiple film layers, a film layer having the first category metal includes at least two types of metals in total.

In some embodiments, at least two film layers located on the side of the first light-emitting layer away from the first electrode in the light-emitting device each include a same type of metal.

In some embodiments, the charge generation layer includes a first charge generation sub-layer and a second charge generation sub-layer, and the first charge generation sub-layer is located between the first light-emitting unit and the second charge generation sub-layer. The first charge generation sub-layer includes at least one type of the second category metal.

In some embodiments, a proportion of a volume of the second category metal in the first charge generation sub-layer to a volume of the first charge generation sub-layer is less than or equal to 1%.

In some embodiments, the second electrode includes two types of the first category metal, where a ratio of volumes of the two types of the first category metal is in a range of 100:1 to 1:100.

In some embodiments, in the light-emitting device, a ratio of a total volume of the first category metal to a total volume of the second category metal is less than or equal to 20:1.

In some embodiments, in the light-emitting device, a proportion of a total volume of the second category metal to a total volume of the first category metal and the second category metal is greater than or equal to 5%.

In some embodiments, at least one of the first film layer, the second film layer and the third film layer includes a host material and a doping material including metal, the doping material being doped in the host material.

In some embodiments, at least one of the first film layer, the second film layer and the third film layer includes a first sub-layer, and a second sub-layer located on a side of the first sub-layer, the first sub-layer and/or the second sub-layer including metal.

In some embodiments, at least one type of the at least three types of metals is both a non-alkaline earth metal and a non-alkali metal.

In some embodiments, a proportion of a volume of the metal in the at least three types of metals that is both the non-alkaline earth metal and the non-alkali metal to a volume of the at least three types of metals is greater than or equal to 5%.

In another aspect, a display panel is provided. The display panel includes a pixel defining layer and light-emitting devices. The pixel defining layer is provided with a plurality of light-emitting openings. The light-emitting devices are each the light-emitting device as described in any of the above embodiments, and are located in the plurality of light-emitting openings.

### BRIEF DESCRIPTION OF THE DRAWINGS

In order to describe technical solutions in the present disclosure more clearly, the accompanying drawings to be used in some embodiments of the present disclosure will be introduced briefly. Obviously, the accompanying drawings to be described below are merely drawings of some embodiments of the present disclosure, and a person of ordinary skill in the art can obtain other drawings according to those drawings. In addition, the accompanying drawings in the following description may be regarded as schematic diagrams, but are not limitations on actual sizes of products, actual processes of methods and actual timings of signals involved in the embodiments of the present disclosure.

FIG. 1 is a perspective view of a display panel, in accordance with some embodiments;

FIG. 2 is a cross-sectional view of the display panel taken along the line A-A′, in accordance with the embodiments shown in FIG. 1;

FIG. 3 to FIG. 7 are diagrams each showing an arrangement structure of sub-pixel regions in a display panel, in accordance with some embodiments;

FIG. 8 is a cross-sectional view of a display panel, in accordance with some embodiments;

FIG. 9 is an enlarged view of three regions FD1, FD2 and FD3 in FIG. 2 in some embodiments;

FIG. 10 is an enlarged view of three regions FD1, FD2 and FD3 in FIG. 2 in some embodiments;

FIG. 11 is an enlarged view of three regions FD1, FD2 and FD3 in FIG. 2 in some embodiments;

FIG. 12 is a structural diagram of a light-emitting device in a display panel, in accordance with some embodiments;

FIG. 13 is an enlarged view of three regions FD1, FD2 and FD3 in FIG. 2 in some embodiments; and

FIG. 14 is a curve graph of current densities of second electrodes in display panels of different schemes under different driving voltages, in accordance with some embodiments.

### DESCRIPTION OF THE INVENTION

The technical solutions in some embodiments of the present disclosure will be described clearly and completely with reference to the accompanying drawings. Obviously, the described embodiments are merely some but not all embodiments of the present disclosure. All other embodiments obtained by a person of ordinary skill in the art based on embodiments provided by the present disclosure shall be included in the protection scope of the present disclosure.

Unless the context requires otherwise, throughout the specification and the claims, the term “comprise” is construed as an open and inclusive meaning, i.e., “including, but not limited to”. In the description of the specification, the terms such as “one embodiment”, “some embodiments”, “exemplary embodiments”, “example”, “specific example”, or “some examples” are intended to indicate that specific features, structures, materials, or characteristics related to the embodiment(s) or example(s) are included in at least one embodiment or example of the present disclosure. Schematic representations of the above terms do not necessarily refer to the same embodiment(s) or example(s). In addition, the specific features, structures, materials, or characteristics may be included in any one or more embodiments or examples in any suitable manner.

Hereinafter, the terms “first”, “second”, etc., are used for descriptive purposes only, and are not to be construed as indicating or implying a relative importance or implicitly indicating a number of indicated technical features. Thus, features defined by “first” or “second” may explicitly or implicitly include one or more of the features. In the description of the embodiments of the present disclosure, the term “a/the plurality of (multiple)” means two or more unless otherwise specified.

In the description of some embodiments, the term “electrically connected” may be used. For example, the term “electrically connected” may be used in the description of some embodiments to indicate that two or more components are in electrical contact with each other.

The phrase “A and/or B” includes the following three combinations: only A, only B, and a combination of A and B.

The phrase “applicable to” or “configured to” as used herein indicates an open and inclusive expression, which does not exclude devices that are applicable to or configured to perform additional tasks or steps.

The term “substantially” as used herein includes a stated value and an average value within an acceptable range of deviation of a particular value determined by a person of ordinary skill in the art, considering measurement in question and errors associated with measurement of a particular quantity (i.e., limitations of a measurement system).

The “ratio between C and D” herein may refer to a ratio between a volume of C and a volume of D.

Exemplary embodiments are described herein with reference to section views and/or plan views as idealized exemplary drawings. In the accompanying drawings, thicknesses of layers and sizes of regions are enlarged for clarity. Therefore, variations in shapes with respect to the accompanying drawings due to, for example, manufacturing technologies and/or tolerances may be envisaged. Therefore, the exemplary embodiments should not be construed as being limited to the shapes of the regions shown herein, but including deviations in shape due to, for example, manufacturing. For example, an etched region shown as a rectangle shape generally has a curved feature. Therefore, the regions shown in the accompanying drawings are schematic in nature, and their shapes are not intended to show actual shapes of regions in a device, and are not intended to limit the scope of the exemplary embodiments.

With the rapid development of OLED display panels, Tandem OLED display panels have become an important development direction of OLED display technologies. The Tandem OLED is composed of more than two layers of light-emitting units, in which a charge generation layer is introduced between the two layers of light-emitting units to achieve the effect of the upper and lower layers of light-emitting units emitting light simultaneously. Therefore, the Tandem OLED has the advantage of high brightness.

However, the inventors of the present disclosure found that due to the thick stacked structure of the Tandem OLED, organic layers therein have limited charge transport capability, so the injection and transport of electrons are limited to a certain extent, thus resulting in a problem of an overall high driving voltage of a light-emitting device.

In light of this, some embodiments of the present disclosure provide a light-emitting device and a display panel, which will be respectively introduced below.

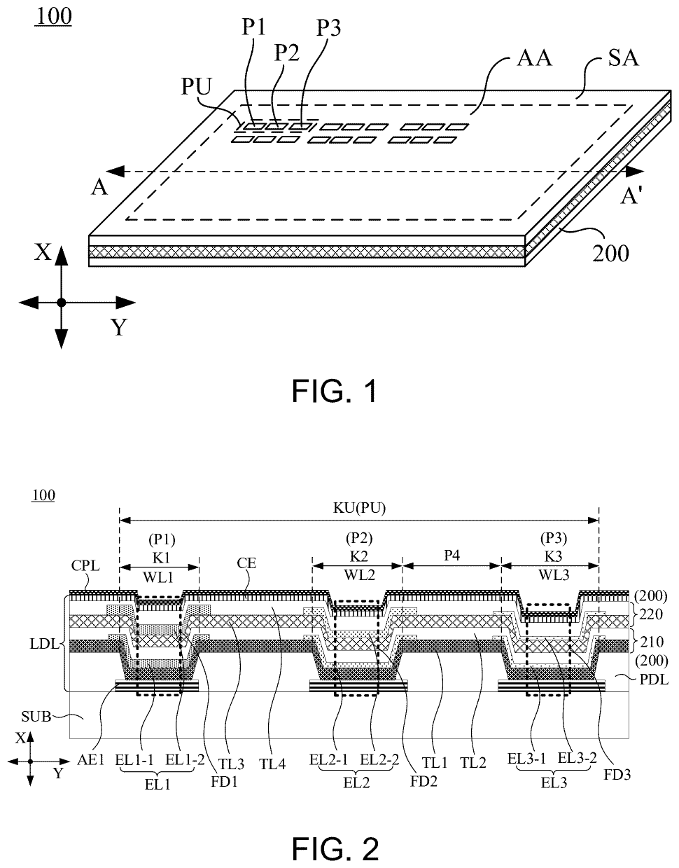

FIG. 1 is a perspective view of a display panel, in accordance with some embodiments. FIG. 2 is a cross-sectional view of the display panel taken along the line A-A′, in accordance with the embodiments shown in FIG. 1. As shown in FIG. 1, the display panel 100 includes a display region AA for displaying images and a non-display region SA that does not display images, in which the non-display region SA surrounds at least one side (e.g., one side or all sides, i.e., including upper and lower sides, and left and right sides) of the display region AA. In some examples, the non-display region SA may be closed to enclose the display region AA, and may be located outside of the display region AA in at least one direction. The display panel 100 in a plan view may be in a shape of rectangle, a circle, an ellipse, a rhombus, a trapezoid, a square or any of other shapes depending on display requirements.

The display panel 100 may be applied to a display apparatus. For example, the display apparatus may be a small-medium sized electronic device such as a tablet computer, a smart phone, a head-mounted display, an automobile navigation unit, a camera, a central information display (CID) provided in a vehicle, a wristwatch-type electronic device or another wearable device, a personal digital assistant (PDA), a portable multimedia player (PMP), or a game console, or a medium-large sized electronic device such as a television, an external billboard, a monitor, a home appliance including a display screen, a personal computer, or a laptop computer. The electronic devices as described above may represent mere examples for the application of the display apparatus, and thus one of ordinary skill in the art may recognize that the display apparatus may also be any of other electronic devices without departing from the spirit and scope of the present disclosure.

As shown in conjunction with FIG. 1, FIG. 2 and FIG. 8, some embodiments of the present disclosure provide a display panel 100. The display panel 100 includes a substrate SUB, a light-emitting device layer LDL, a light extraction layer CPL, and an encapsulation layer TFE.

The substrate SUB includes a plurality of pixel unit regions PU that are repeatedly arranged. Each pixel unit region PU may include a first sub-pixel region P1, a second sub-pixel region P2 and a third sub-pixel region P3 that display different colors. For example, the first sub-pixel region P1 is configured to display red light, the second sub-pixel region P2 is configured to display green light, and the third sub-pixel region P3 is configured to display blue light.

In addition, the pixel unit region PU may further include a non-light-emitting region P4. The non-light-emitting region P4 may be located between the first sub-pixel region P1 and the second sub-pixel region P2, between the second sub-pixel region P2 and the third sub-pixel region P3, and between the third sub-pixel region P3 and the first sub-pixel region P1.

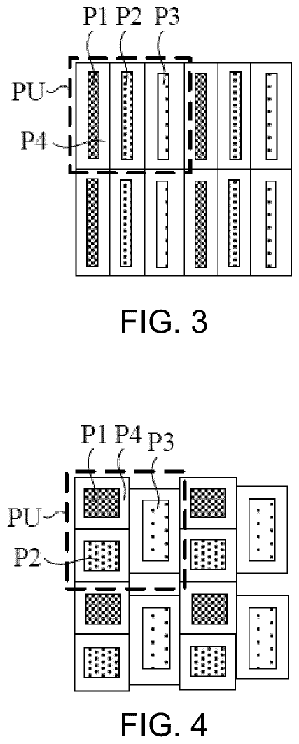

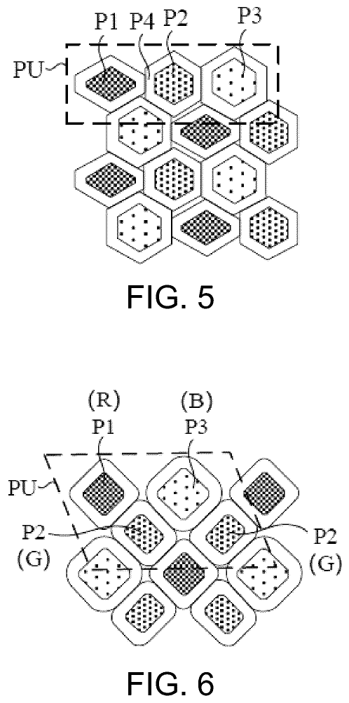

In some examples, as shown in FIG. 3 to FIG. 5, a pixel unit region PU includes one first sub-pixel region P1, one second sub-pixel region P2, and one third sub-pixel region P3. The one first sub-pixel region P1, the one second sub-pixel region P2, and the one third sub-pixel region P3 may be spaced apart from each other along a second direction Y and repeatedly arranged in the display region AA.

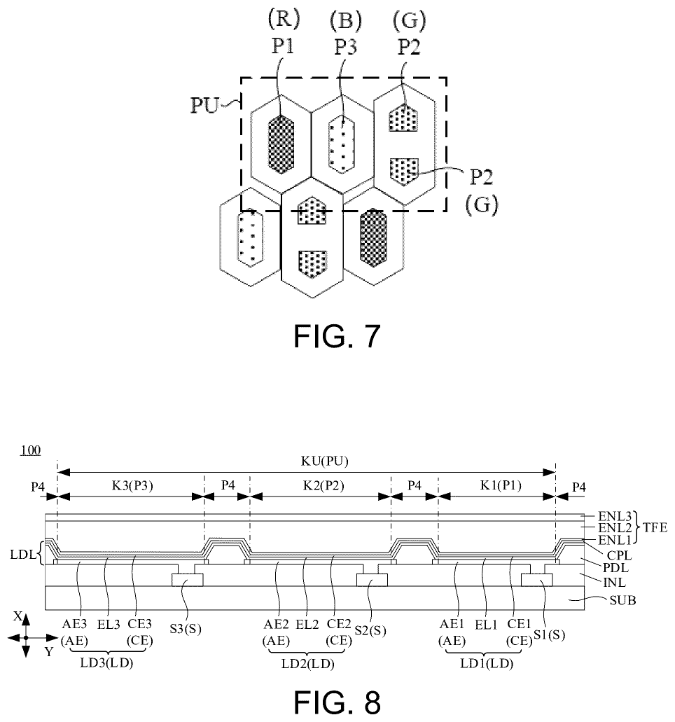

In some examples, as shown in FIG. 6 and FIG. 7, a pixel unit region PU may include two sub-pixel regions for displaying a same color, and the two sub-pixel regions for displaying the same color may be arranged adjacent to each other. For example, a pixel unit region PU includes one red sub-pixel region R, two green sub-pixel regions G and one blue sub-pixel region B, in which the two green sub-pixel regions G in the pixel unit region PU may be arranged adjacent to each other.

In some examples, a pixel unit region PU includes one first sub-pixel region P1, two second sub-pixel regions P2, and one third sub-pixel region P3. The one first sub-pixel region P1, the two second sub-pixel regions P2, and the one third sub-pixel region P3 may be spaced apart from each other along the second direction Y and repeatedly arranged in the display region AA. In this case, the non-light-emitting region P4 may further be located between the two second sub-pixel regions P2.

As shown in FIG. 2, in a pixel unit region PU, the first sub-pixel region P1 has a first width WL1 in the second direction Y (a direction parallel to the substrate SUB), the second sub-pixel region P2 has a second width WL2 in the second direction Y, and the third sub-pixel region P3 has a third width WL3 in the second direction Y, in which the first width WL1, the second width WL2, and the third width WL3 may be different from each other.

As shown in FIG. 8, the display panel 100 may include a plurality of pixel circuits S located on the substrate SUB. A first pixel circuit S1, a second pixel circuit S2, and a third pixel circuit S3 may be included in a pixel unit region PU. For example, the first pixel circuit S1 is located in the first sub-pixel region P1, the second pixel circuit S2 is located in the second sub-pixel region P2, and the third pixel circuit S3 is located in the third sub-pixel region P3. As another example, in at least one of the first pixel circuit S1, the second pixel circuit S2, and the third pixel circuit S3, thin film transistors may be located in the non-light-emitting region P4.

The structure of the pixel circuit has a variety of options, which may be set according to actual needs. For example, the pixel circuit may include at least two transistors (denoted by T) and at least one capacitor (denoted by C). For example, the pixel circuit S may have a “2T1C” structure, a “6T1C” structure, a “7T1C” structure, a “6T2C” structure, or a “7T2C” structure.

In at least one of the first pixel circuit S1, the second pixel circuit S2, and the third pixel circuit S3, a thin film transistor may be a thin film transistor including polysilicon or a thin film transistor including an oxide semiconductor. For example, in a case where the thin film transistor is the thin film transistor including the oxide semiconductor, the thin film transistor may have a top-gate thin film transistor structure. The thin film transistor may be connected to signal lines, in which the signal lines include but are not limited to a gate line, a data line and a power supply line.

As shown in FIG. 8, the display panel 100 may include an insulating layer INL, which may be located on the first pixel circuit S1, the second pixel circuit S2, and the third pixel circuit S3. The insulating layer INL may have a flat surface. The insulating layer INL may be formed by an organic layer. For example, the insulating layer INL may include acrylic resin, epoxy resin, imide resin or ester resin. The insulating layer INL may have through holes exposing electrodes of the first pixel circuit S1, the second pixel circuit S2, and the third pixel circuit S3, so as to achieve an electrical connection.

As shown in conjunction with FIG. 2 and FIG. 8, the display panel 100 may include the light-emitting device layer LDL and a pixel defining layer PDL located on the substrate SUB. The pixel defining layer PDL, which may be formed on the insulating layer INL, defines a plurality of light-emitting openings. For example, the pixel defining layer PDL includes a first light-emitting opening K1 located in the first sub-pixel region P1, a second light-emitting opening K2 located in the second sub-pixel region P2, and a third light-emitting opening K3 located in the third sub-pixel region P3. A plurality of light-emitting devices LD, which are connected to the pixel circuits S, are formed in the light-emitting device layer LDL. The plurality of light-emitting devices LD are located in the plurality of light-emitting openings, respectively. Light-emitting devices LD in a pixel unit region PU include a first light-emitting device LD1 with light-emitting layers EL1, a second light-emitting device LD2 with light-emitting layers EL2, and a third light-emitting device LD3 with light-emitting layers EL3. For example, the first light-emitting device LD1 may be located in the first light-emitting opening K1, the second light-emitting device LD2 may be located in the second light-emitting opening K2, and the third light-emitting device LD3 may be located in the third light-emitting opening K3.

The light-emitting device LD may include a first electrode AE, at least two light-emitting units 200 and a second electrode CE that are stacked in sequence along a first direction X (i.e., a direction perpendicular to the substrate SUB).

In some examples, the display panel 100 is a top-emission display panel. The first electrode, e.g., an anode, is a reflective electrode that can reflect light, and the second electrode CE, e.g., a cathode, is a transmissive electrode that can transmit light. In this way, a microcavity structure is formed between the anode and the cathode.

In some other examples, the display panel 100 is a bottom-emission display panel. The first electrode, e.g., an anode, is a transmissive electrode that can transmit light, and the second electrode CE, e.g., a cathode, is a reflective electrode that can reflect light. In this way, a microcavity structure is formed between the anode and the cathode.

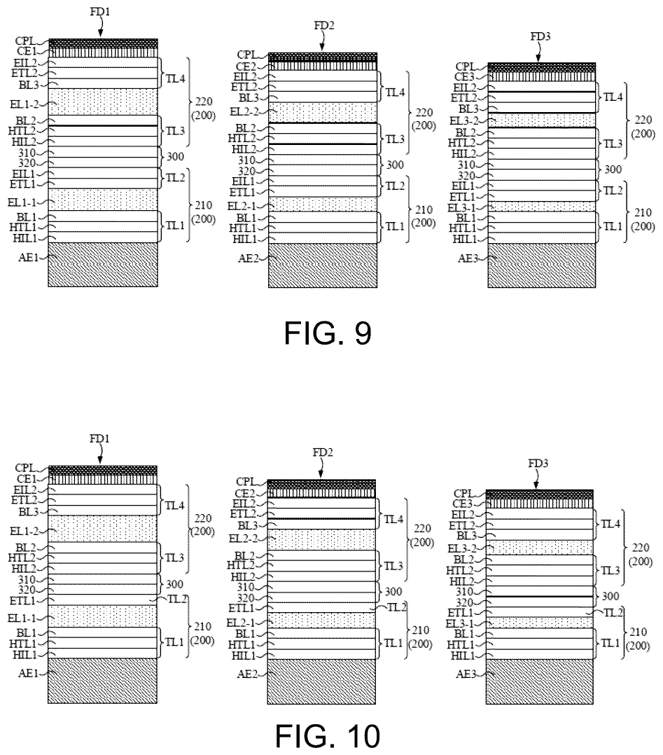

As shown in FIG. 8 and FIG. 9, first electrodes include a first electrode AE1 located in the first sub-pixel region P1, a first electrode AE2 located in the second sub-pixel region P2, and a first electrode AE3 located in the third sub-pixel region P3.

In some embodiments, the first electrode may include a high work function material, for example, may be made of Ag, Mg, Al, Pt, Pd, Au, Ni, Nd, Ir, or Cr metals, or a mixture thereof, or may be made of ITO, IZO or IGZO and any of other transparent conductive oxide materials. A dimension of the first electrode AE in the first direction X may be in a range of 80 nm to 200 nm.

In some examples, the display panel 100 may be a top-emission display panel. The first electrode may include a stacked composite structure of transparent conductive oxide/metal/transparent conductive oxide. A material of the transparent conductive oxide is, for example, ITO or IZO, and a material of the metal is, for example, Au, Ag, Ni or Pt. For example, a structure of the anode is ITO/Ag/ITO. A dimension of the metal in the first direction X may be in a range of 50 nm to 150 nm; and a dimension of the transparent conductive oxide in the first direction X may be in a range of 5 nm to 15 nm. In addition, an average reflectivity of the first electrode for visible light may be in a range of 85% to 95%.

In some examples, the display panel 100 is a bottom-emission display panel. The first electrode may include a transparent conductive oxide such as ITO, IZO or IGZO.

In some embodiments, the second electrode CE may include a metal material or an alloy material. The metal material is, for example, Al, Ag or Mg; and the alloy material is, for example, Mg:Ag alloy or Al:Li alloy. For example, the cathode includes Mg:Ag alloy, in which a ratio between the Mg element and the Ag element may be in a range of 3:7 to 1:9.

In some examples, the display panel 100 is a top-emission display panel. A dimension of the second electrode CE in the first direction X may be in a range of 10 nm to 20 nm. An average transmittance of the second electrode CE for visible light may be greater than or equal to 50%, such as 50%, 55%, 60%, 65%, 70%, 75%, 80%, or 85%.

In some other examples, the display panel 100 is a bottom-emission display panel. The dimension of the second electrode CE in the first direction may be greater than or equal to 80 nm, such as 80 nm, 85 nm, 90 nm, or 95 nm. In this way, it may be ensured that the second electrode CE, serving as a reflective electrode, has a relatively good reflectivity for light.

As shown in FIG. 8 and FIG. 9, second electrodes CE include a second electrode CE1 located in the first sub-pixel region P1, a second electrode CE2 located in the second sub-pixel region P2, and a second electrode CE3 located in the third sub-pixel region P3.

The at least two light-emitting units 200 between the first electrode AE and the second electrode CE may be stacked in the first direction X. The number of the light-emitting units 200 between the first electrode and the second electrode CE may be two, three, or any of other numbers, which is not limited here.

As shown in FIG. 2 and FIG. 9, in some examples, a first light-emitting unit 210 and a second light-emitting unit 220 are between the first electrode and the second electrode CE. That is, there are two light-emitting units 200 between the first electrode and the second electrode CE. The first light-emitting unit 210 may be in direct contact with the first electrode; and the second light-emitting unit 220 is located between the first light-emitting unit 210 and the second electrode CE, and the second light-emitting unit 220 may be in direct contact with the second electrode CE.

The first light-emitting unit 210 includes a first light-emitting layer (e.g., EL1-1/EL2-1/EL3-1), a first transport layer TL1 and a second transport layer TL2. The first transport layer TL1 is located between the first light-emitting layer and the first electrode AE. It can be understood that a dimension of the first transport layer TL1 in the first direction X is equal to a distance spaced between the first electrode AE and the first light-emitting layer in the first direction. The first transport layer TL1 is configured to transport holes from the first electrode AE to the first light-emitting layer. The second transport layer TL2 is located between the first light-emitting layer and the second light-emitting unit 220. It can be understood that a dimension of the second transport layer TL2 in the first direction X is equal to a distance spaced between the first light-emitting layer and the second light-emitting unit 220 in the first direction X. The second transport layer TL2 is configured to transport electrons to the first light-emitting layer. In this way, the holes and the electrons recombine in the first light-emitting layer, enabling the first light-emitting layer to emit light.

The second light-emitting unit 220 includes a second light-emitting layer (e.g., EL1-2/EL2-2/EL3-2), a third transport layer TL3 and a fourth transport layer TL4. The third transport layer TL3 is located between the second light-emitting layer and the first light-emitting unit 210. It can be understood that a dimension of the third transport layer TL3 in the first direction X is equal to a distance spaced between the first light-emitting unit 210 and the second light-emitting layer in the first direction X. The third transport layer TL3 is configured to transport holes to the second light-emitting layer. The fourth transport layer TL4 is located between the second light-emitting layer and the second electrode CE. It can be understood that a dimension of the fourth transport layer TL4 in the first direction X is equal to a distance between the second light-emitting layer and the second electrode CE in the first direction X. The fourth transport layer TL4 is configured to transport electrons from the second electrode CE to the second light-emitting layer. In this way, the holes and the electrons recombine in the second light-emitting layer, enabling the second light-emitting layer to emit light.

As shown in FIG. 9, in some embodiments, the light-emitting device further includes a charge generation layer 300 located between two adjacent light-emitting units 200. For example, the charge generation layer 300 includes a P-type charge generation sub-layer 310 and an N-type charge generation sub-layer 320. The N-type charge generation sub-layer 320 may be in direct contact with the first light-emitting unit 210. For example, the N-type charge generation sub-layer 320 is in direct contact with the second transport layer TL2 to provide electrons to the first light-emitting unit 210. The P-type charge generation sub-layer 310 may be in direct contact with the second light-emitting unit 220. For example, the P-type charge generation sub-layer 310 is in direct contact with the third transport layer TL3 to provide holes to the second light-emitting unit 220.

In some examples, the second transport layer TL2 is configured to transport electrons provided by a charge generation layer 300 to the first light-emitting layer, so that holes provided by the first electrode AE and electrons provided by the charge generation layer 300 recombine in the first light-emitting layer for light emission. The third transport layer TL3 is configured to transport holes provided by a charge generation layer 300 to the second light-emitting layer, so that holes provided by the charge generation layer 300 and electrons provided by the second electrode CE recombine in the second light-emitting layer for light emission.

The charge generation layer 300 may include metal, non-doped organic matter, an organic PN junction composed of P-type doping and N-type doping, or a metal oxide, which is not limited here.

In some embodiments, in a same light-emitting device, an absolute value of a difference between a wavelength of light emitted by the first light-emitting layer and a wavelength of light emitted by the second light-emitting layer may be less than or equal to 10 nm, such as 10 nm, 8 nm, 5 nm, or 3 nm.

It can be understood that two light-emitting units 200 in the same light-emitting device emit the same or similar light. In this way, the concentration of the spectral superposition of the two light-emitting units 200 may be improved, improving the color purity and the light extraction efficiency of the light.

For example, the light-emitting device is a blue light-emitting device. A wavelength of light emitted by the first light-emitting layer in the blue light-emitting device is 460 nm, and a wavelength of light emitted by the second light-emitting layer in the blue light-emitting device may be 450 nm to 470 nm. In this way, the light extraction efficiency of light corresponding to a waveband with overlapping wavelengths in the light-emitting device may be improved.

In some embodiments, in a same light-emitting device, a difference ratio between a wavelength of light emitted by the first light-emitting layer at the spectral peak and a wavelength of light emitted by the second light-emitting layer at the spectral peak is less than 5%.

It can be understood that the wavelengths at the spectral peaks of the two types of light emitted by the two light-emitting units 200 in the same light-emitting device are the same or similar. In this way, the concentration of the spectral superposition of the two light-emitting units 200 may be improved, improving the color purity and the light extraction efficiency of the light.

For example, the light-emitting device is a red light-emitting device. A wavelength of light emitted by the first light-emitting layer in the red light-emitting device at the spectral peak is 530 nm, and a wavelength of light emitted by the second light-emitting layer in the red light-emitting device at the spectral peak may be in a range of 504 nm to 557 nm. In this way, the light extraction efficiency of light corresponding to a waveband with overlapping wavelengths in the light-emitting device may be improved.

As shown in FIG. 9, in some examples, the first transport layer TL1 may include a first hole injection layer HIL1 and a first hole transport layer HTL1. The first hole injection layer HIL1 is located between the first electrode AE and the first hole transport layer HTL1. The first hole injection layer HIL1 is configured to inject holes from the first electrode AE into the first hole transport layer HTL1. The first hole transport layer HTL1 is located between the first hole injection layer HIL1 and the first light-emitting layer. The first hole transport layer HTL1 is configured to transport holes injected by the first hole injection layer HIL1 to the first light-emitting layer, so that the holes recombine with electrons in the first light-emitting layer, achieving the light emission of the first light-emitting layer.

As shown in FIG. 9, in some examples, the first transport layer TL1 may further include a first exciton blocking layer BL1. The first exciton blocking layer BL1 may be located between the first hole transport layer HTL1 and the first light-emitting layer, and the first exciton blocking layer BL1 is configured to block electrons in the first light-emitting layer from moving in a direction approaching the first electrode. Therefore, the first exciton blocking layer BL1 may also be called an electron blocking layer (EBL).

As shown in FIG. 9 to FIG. 11, in some examples, the second transport layer TL2 may include a first electron transport layer ETL1 and/or a first electron injection layer EIL1.

For example, as shown in FIG. 10, the second transport layer TL2 includes only the first electron transport layer ETL1, and the first electron transport layer ETL1 is in direct contact with both the first light-emitting layer and the N-type charge generation sub-layer 320. The first electron transport layer ETL1 is configured to transport electrons provided by the N-type charge generation sub-layer 320 to the first light-emitting layer, so that the electrons recombine with holes in the first light-emitting layer, achieving the light emission of the first light-emitting layer.

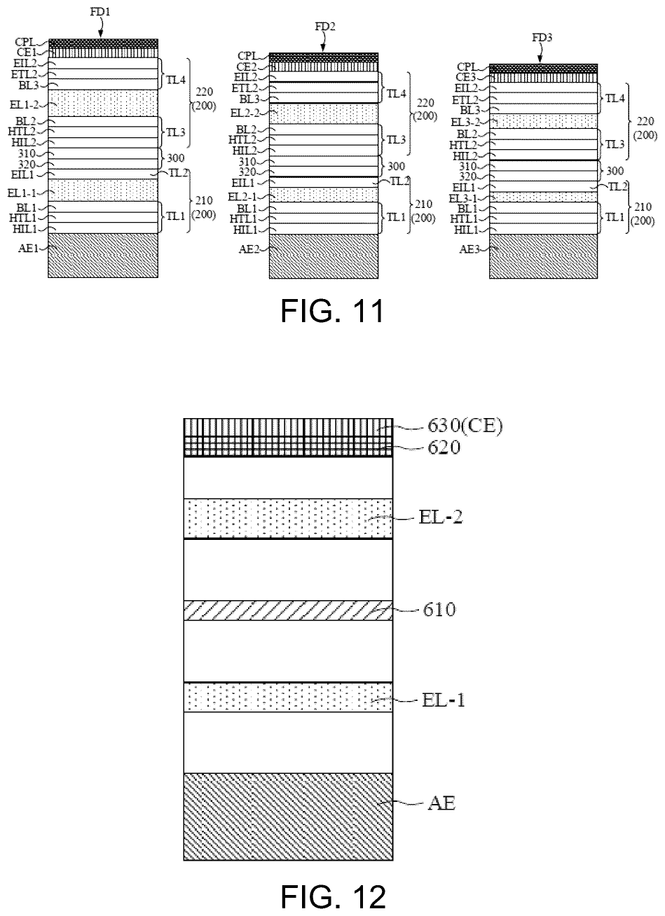

As another example, as shown in FIG. 11, the second transport layer TL2 includes only the first electron injection layer EIL1, and the first electron injection layer EIL1 is in direct contact with both the first light-emitting layer and the N-type charge generation sub-layer 320. The first electron injection layer EIL1 is configured to inject electrons provided by the N-type charge generation sub-layer into the first light-emitting layer, so that the electrons recombine with holes in the first light-emitting layer, achieving the light emission of the first light-emitting layer.

As another example, as shown in FIG. 9, the second transport layer TL2 includes the first electron transport layer ETL1 and the first electron injection layer EIL1. The first electron injection layer EIL1 is located between the first electron transport layer ETL1 and the N-type charge generation sub-layer 320, and the first electron injection layer EIL1 is configured to inject electrons provided by the N-type charge generation sub-layer 320 into the first electron transport layer ETL1. The first electron transport layer ETL1 is located between the first electron injection layer EIL1 and the first light-emitting layer, and the first electron transport layer ETL1 is configured to transport electrons injected by the first electron injection layer EIL1 to the first light-emitting layer, so that the electrons recombine with holes in the first light-emitting layer, achieving the light emission of the first light-emitting layer.

As shown in FIG. 9, in some examples, the third transport layer TL3 may include a second hole injection layer HIL2 and a second hole transport layer HTL2. The second hole injection layer HIL2 is located between the P-type charge generation sub-layer 310 and the second hole transport layer HTL2, and the second hole injection layer HIL2 is configured to inject holes provided by the P-type charge generation sub-layer 310 into the second hole transport layer HTL2. The second hole transport layer HTL2 is located between the second hole injection layer HIL2 and the second light-emitting layer, and the second hole transport layer HTL2 is configured to transport holes injected by the second hole injection layer HIL2 to the second light-emitting layer, so that the holes recombine with electrons in the second light-emitting layer, achieving the light emission of the first light-emitting layer.

As shown in FIG. 9, in some examples, the third transport layer TL3 may further include a second exciton blocking layer BL2. The second exciton blocking layer BL2 may be located between the second hole transport layer HTL2 and the second light-emitting layer, and the second exciton blocking layer BL2 is configured to block electrons in the second light-emitting layer from moving in a direction approaching the first electrode. Therefore, the second exciton blocking layer BL2 may also be called an electron blocking layer.

As shown in FIG. 9, in some examples, the fourth transport layer TL4 may include a second electron transport layer ETL2 and a second electron injection layer EIL2. The second electron injection layer EIL2 is located between the second electron transport layer ETL2 and the second electrode, and the second electron injection layer EIL2 is configured to inject electrons provided by the second electrode into the second electron transport layer ETL2. The second electron transport layer ETL2 is located between the second electron injection layer EIL2 and the second light-emitting layer, and the second electron transport layer ETL2 is configured to transport electrons injected by the second electron injection layer EIL2 to the second light-emitting layer, so that the electrons recombine with holes in the second light-emitting layer, achieving the light emission of the second light-emitting layer.

As shown in FIG. 9, in some examples, the fourth transport layer TL4 may further include a third exciton blocking layer BL3. The third exciton blocking layer BL3 may be located between the second electron transport layer ETL2 and the second light-emitting layer, and the third exciton blocking layer BL3 is configured to block holes in the second light-emitting layer from moving in a direction approaching the second electrode. Therefore, the third exciton blocking layer BL3 may also be called a hole blocking layer.

In some examples, at least one of the first hole injection layer HIL1 and the second hole injection layer HIL2 may include a material with strong hole injection capabilities such as copper phthalocyanine (CuPc) or HATCN, forming a single-layer film structure. In some other examples, at least one of the first hole injection layer HIL1 and the second hole injection layer HIL2 may include a P-type doped hole injection material or a P-type doped material, such as NPB:F4TCNQ or TAPC:MnO₃.

In some examples, the first hole injection layer HIL1 may include a first host material and a first doping material, in which a proportion of the first doping material to the first host material and the first doping material as a whole may be 3%. For example, the first host material may be NPB (N,N′-bis(naphthyl-1-yl)-N,N′-bis(phenyl)benzidine), and the first doping material may be a P-type doping material, such as F4TCNQ.

In some examples, the second hole injection layer HIL2 may include a second host material and a second doping material, in which a proportion of the second doping material to the second host material and the second doping material as a whole may be 8%. The second host material may be the same as the first host material, and the second doping material may be the same as the first doping material.

In some examples, at least one of the first hole transport layer HTL1 and the second hole transport layer HTL2 may include a carbazole-based material with relatively high hole mobility, or any of other materials with relatively high hole mobility. The work function of at least one of the first hole transport layer HTL1 and the second hole transport layer HTL2 may be in a range of −5.2 eV to −5.6 eV.

In some examples, at least one of the first electron transport layer ETL1 and the second electron transport layer ETL2 may include a triazine-based material with relatively high electron mobility, or any of other materials with relatively high electron mobility. A dimension of at least one of the first electron transport layer ETL1 and the second electron transport layer ETL2 in the first direction X may be in a range of 5 nm to 50 nm.

In some examples, the second electron transport layer ETL2 may include a third host material and a third doping material, in which a proportion of the third doping material to the third host material and the third doping material as a whole may be 50%. For example, the third host material may be TPBI (1,3,5-tris(1-phenyl-1H-benzimidazol-2-yl)benzene), and the third doping material may be LiQ, LiF, Li, or Yb.

In some examples, a dimension of at least one of the first electron injection layer EIL1 and the second electron injection layer EIL2 in the first direction may be in a range of 0.5 nm to 20 nm.

In some examples, the first electron injection layer EIL1 may include a fourth host material and a fourth doping material, in which a proportion of the fourth doping material to the fourth host material and the fourth doping material as a whole may be 2%. The fourth host material may be the same as the third host material, and the fourth doping material may be the same as the third doping material.

In some examples, the first electron injection layer EIL1 may include at least one type of metal element. The metal elements may be lithium (Li), ytterbium (Yb), cesium (Cs), calcium (Ca) and any of other metals. The work function of the metal element in the first electron injection layer EIL1 may be greater than −3.5 eV.

For example, the first electron injection layer EIL1 includes only lithium element. As another example, the first electron injection layer EIL1 includes both ytterbium element and cesium element.

In some embodiments, a doping proportion of the metal element in the first electron injection layer EIL1 is less than 8%. It can be understood that a proportion of the total volume of the metal element in the first electron injection layer EIL1 to the volume of the first electron injection layer EIL1 is less than or equal to 8%, such as 8%, 7.5%, 7%, 6.5%, 6%, 5.5%, 5%, 4.5%, 4%, 3.5%, 3%, 2.5%, 2%, 1.5%, or 1%.

For example, the first electron injection layer EIL1 includes only lithium element, where a proportion of the volume of the lithium element to the volume of the first electron injection layer EIL1 is 7%. As another example, the first electron injection layer EIL1 includes both ytterbium element and cesium element, where a proportion of the volume of the ytterbium element to the volume of the first electron injection layer EIL1 is 2.5%, and a proportion of the volume of the cesium element to the volume of the first electron injection layer EIL1 is 4%, so a proportion of the total volume of the metal elements to the volume of the first electron injection layer EIL1 is 6.5%.

In some examples, a dimension of at least one of the first exciton blocking layer BL1, the second exciton blocking layer BL2 and the third exciton blocking layer BL3 in the first direction may be in a range of 2 nm to 15 nm.

In some examples, at least one of the second electron injection layer EIL2 and the second electron transport layer ETL2 includes at least one type of metal element that is the same as the metal element included in the first electron injection layer EIL1.

It can be understood that at least one type of multiple types of metal elements included in the second electron injection layer EIL2 and the second electron transport layer ETL2 is the same as at least one type of multiple types of metal elements included in the first electron injection layer EIL1.

For example, the second electron injection layer EIL2 and/or the second electron transport layer ETL2 includes lithium element, and the first electron injection layer EIL1 includes lithium element and calcium element. As another example, the second electron injection layer EIL2 includes lithium element, the second electron transport layer ETL2 includes calcium element, and the first electron injection layer EIL1 includes lithium element and calcium element. As yet another example, the second electron injection layer EIL2 includes aluminum (Al) element, the second electron transport layer ETL2 includes calcium element, and the first electron injection layer EIL1 includes calcium element and cesium element.

At least one of the second electron injection layer EIL2 and the second electron transport layer ETL2 includes at least one type of metal element that is the same as the metal element included in the first electron injection layer EIL1, so that at least one of the second electron injection layer EIL2 and the second electron transport layer ETL2 has the same or similar work function as the first electron injection layer EIL1, thereby improving the electron injection and transport capabilities in the light-emitting device and reducing a driving voltage of the light-emitting device.

In some embodiments, multiple film layers located on a side of the first light-emitting layer away from the first electrode in the light-emitting device collectively include at least three types of metals.

As shown in FIG. 9, the multiple film layers located on the side of the first light-emitting layer (e.g., EL1-1, EL2-1, or EL3-1) away from the first electrode AE in the light-emitting device may include the first electron transport layer ETL1, the first electron injection layer EIL1, the N-type charge generation sub-layer 320, the P-type charge generation sub-layer 310, the second hole injection layer HIL2, the second hole transport layer HTL2, the second exciton blocking layer BL2, the second light-emitting layer, the third exciton blocking layer BL3, the second electron transport layer ETL2, the second electron injection layer EIL2, and the second electrode CE.

It can be understood that one or more of the multiple film layers collectively include at least three types of metals. By way of example, there is a single film layer that includes at least three types of metals. For example, the second electrode CE includes three types of metals. By way of example, there are multiple film layers that include at least three types of metals, where different film layers include metals different from each other. For example, the second hole injection layer HIL2 includes a first type of metal, the second hole transport layer HTL2 includes a second type of metal, and the N-type charge generation sub-layer 320 includes a third type of metal. By way of example, there are multiple film layers that include at least three types of metals, where different film layers may include a same type of metal. For example, the second hole injection layer HIL2 includes a first type of metal and a second type of metal, and the second hole transport layer HTL2 includes the second type of metal and a third type of metal.

In the light-emitting device provided by the embodiments of the present disclosure, by providing at least three types of metals in the multiple film layers located on the side of the first light-emitting layer away from the first electrode in the light-emitting device, it is possible to enhance the coordination relationship between the work functions of different metals in the light-emitting device and improve the overall electron injection capability of the light-emitting device, thereby improving the light extraction efficiency of the light-emitting device and reducing the driving voltage required by the light-emitting device.

In some embodiments, in the multiple film layers located on the side of the first light-emitting layer away from the first electrode in the light-emitting device, at least three film layers each include metal.

For example, the first electron transport layer ETL1, the second electron transport layer ETL2, and the second electrode CE each include metal, and the first electron transport layer ETL1, the second electron transport layer ETL2, and the second electrode CE collectively include at least three types of metals.

As another example, the N-type charge generation sub-layer 320, the second electron injection layer EIL2, and the second electrode CE each include metal, and the N-type charge generation sub-layer 320, the second electron injection layer EIL2, and the second electrode CE collectively include at least three types of metals.

As yet another example, the P-type charge generation sub-layer 310, the second hole injection layer HIL2, the second hole transport layer HTL2, and the second electron injection layer EIL2 each include metal, and the P-type charge generation sub-layer 310, the second hole injection layer HIL2, the second hole transport layer HTL2, and the second electron injection layer EIL2 collectively include at least three types of metals.

In the above embodiments, by providing metals in at least three film layers located on the side of the first light-emitting layer away from the first electrode in the light-emitting device, it is possible to enhance the coordination relationship between the work functions of the metals in the at least three film layers, expand the degree of work function coordination in the light-emitting device, and improve the overall electron injection capability of the light-emitting device, thereby improving the light extraction efficiency of the light-emitting device and reducing the driving voltage required by the light-emitting device.

The following description takes the light-emitting device shown in FIG. 9 as an example. However, it should be considered that it is not limited to the structure shown in FIG. 9. It should be considered that the structures shown in FIG. 10 and FIG. 11 are also consistent with the subsequent description, and the only difference lies in the presence or absence of the first electron transport layer ETL1 and the first electron injection layer EIL1, which does not affect the effects of each embodiment.

As shown in FIG. 12, in some examples, at least three film layers include a first film layer 610, a second film layer 620 and a third film layer 630 that are arranged in sequence along a direction from the first electrode AE to the second electrode CE. The first film layer 610, the second film layer 620 and the third film layer 630 are all located on the side of the first light-emitting layer EL-1 away from the first electrode AE.

Here, an absolute value of work function of metal in the third film layer 630 is greater than an absolute value of work function of metal in the second film layer 620, and the absolute value of the work function of the metal in the third film layer 630 is greater than an absolute value of work function of metal in the first film layer 610.

It will be noted that an absolute value of work function of metal in a film layer may refer to a sum of products, each product being a product of an absolute value of work function of each metal in multiple metals included in the film layer and a proportion of each metal to the multiple metals. For example, the second electrode includes one type of metal, and an absolute value of work function of this type of metal is an absolute value of work function of metal in the second electrode. As another example, the second electrode includes silver (Ag) element and magnesium (Mg) element, and a product of an absolute value of work function of the silver (Ag) element and a proportion of the silver (Ag) element to the silver (Ag) element and the magnesium (Mg) element, plus a product of an absolute value of work function of the magnesium (Mg) element and a proportion of the magnesium (Mg) element to the silver (Ag) element and the magnesium (Mg) element is the absolute value of the work function of the metals in the second electrode. The above is only an example in which a film layer includes 1 or 2 types of metals, which does not limit a film layer to include only 1 or 2 types of metals, and a film layer can also include 3 types of metals, 4 types of metals or more.

As shown in FIG. 12, the absolute value of the work function of the metal in the third film layer 630 is greater than the absolute value of the work function of the metal in the second film layer 620 and the absolute value of the work function of the metal in the first film layer 610 which are away from the second electrode. Since electrons move from a position with a large absolute value of the work function along a direction with a small absolute value of the work function, the above arrangement may improve the capability of electrons to move in a direction from the second electrode to the first electrode, thus improving the overall electron injection capability of the light-emitting device, thereby improving the light extraction efficiency of the light-emitting device and reducing the driving voltage required for the light-emitting device.

In some embodiments, the at least three types of metals include first category metal and second category metal.

In some examples, metal with work function less than −3.5 eV is called the first category metal, and metal with work function greater than −3.5 eV is called the second category metal.

The first category metal may include at least one of high work function metals such as silver (Ag), aluminum (Al), gold (Au), copper (Cu), magnesium (Mg), molybdenum (Mo), and tin (Sn). The second category metal may include at least one of low work function metals such as lithium (Li), ytterbium (Yb), cesium (Cs), and calcium (Ca).

For example, the second electrode includes two types of the first category metal and one type of the second category metal, in this case, the second electrode may include Mg:Ag alloy and Yb element. As another example, the second electron injection layer EIL2 includes one type of the second category metal, in this case, the second electron injection layer EIL2 may include Yb element.

In some examples, work function of the first category metal may be in a range of −5.2 eV to −3.5 eV, such as −5.2 eV, −4.25 eV, −4 eV, −3.8 eV, −3.7 eV, or −3.5 eV. Alternatively, the work function of the first category metal may be −3.3 eV or −3 eV.

As shown in FIG. 12, in some embodiments, the second light-emitting unit 220 includes a second light-emitting layer EL-2. In the light-emitting device, at least one type of the second category metal is included in a side of the second light-emitting layer EL-2 proximate to the first electrode AE, and at least one type of the first category metal and at least one type of the second category metal are included in a side of the second light-emitting layer EL-2 away from the first electrode.

As shown in conjunction with FIG. 9 and FIG. 12, in the light-emitting device, multiple film layers located on the side of the second light-emitting layer EL-2 proximate to the first electrode AE include the first electron transport layer ETL1, the first electron injection layer EIL1, the N-type charge generation sub-layer 320, the P-type charge generation sub-layer 310, the second hole injection layer HIL2, the second hole transport layer HTL2, and the second exciton blocking layer BL2. At least one of these film layers includes at least one type of the second category metal.

For example, one film layer located on the side of the second light-emitting layer EL-2 proximate to the first electrode AE includes one type of the second category metal. For example, the N-type charge generation sub-layer 320 includes Yb element.

For example, one film layer located on the side of the second light-emitting layer EL-2 proximate to the first electrode AE includes multiple types of the second category metal. For example, the first electron injection layer EIL1 includes Li element and Cs element.

For example, multiple film layers located on the side of the second light-emitting layer EL-2 proximate to the first electrode AE each include a same type of the second category metal. For example, the N-type charge generation sub-layer 320 includes Yb element, and the second hole injection layer HIL2 also includes Yb element.

For example, multiple film layers located on the side of the second light-emitting layer EL-2 proximate to the first electrode AE each include different type(s) of the second category metal. For example, the first electron injection layer EIL1 includes Li element and Cs element, and the first electron transport layer ETL1 includes Yb element.

As shown in conjunction with FIG. 9 and FIG. 12, in the light-emitting device, multiple film layers located on the side of the second light-emitting layer EL-2 away from the first electrode AE include the third exciton blocking layer BL3, the second electron transport layer ETL2, the second electron injection layer EIL2, and the second electrode CE. At least one of these film layers includes at least one type of the first category metal and at least one type of the second category metal.

For example, one film layer located on the side of the second light-emitting layer EL-2 away from the first electrode AE includes at least one type of the first category metal and at least one type of the second category metal. For example, the second electrode CE includes Mg:Ag alloy and Yb element.

For example, multiple film layers located on the side of the second light-emitting layer EL-2 away from the first electrode AE collectively include at least one type of the first category metal and at least one type of the second category metal. For example, the second electron transport layer ETL2 includes Li element, the second electron injection layer EIL2 includes Cs element, and the second electrode CE includes Cu element. As another example, the second electrode CE includes Mg:Ag alloy, and the second electron injection layer EIL2 includes Yb element. As yet another example, the second electrode CE includes Mg:Ag alloy and Yb element, and the second electron injection layer EIL2 includes Yb element.

In some examples, as shown in FIG. 12, the first film layer 610 is located on the side of the second light-emitting layer proximate to the first electrode, and the second film layer 620 and the third film layer 630 are located on the side of the second light-emitting layer away from the first electrode.

It can be understood that the first film layer 610 includes at least one type of the second category metal, and the second film layer 620 and the third film layer 630 collectively include at least one type of the first category metal and at least one type of the second category metal.

For example, the first film layer 610 is the first electron injection layer EIL1, including Cs element; the second film layer 620 is the second electron transport layer ETL2, including Yb element; and the third film layer 630 is the second electrode CE, including Ag element.

For example, the first film layer 610 is the N-type charge generation sub-layer 320, including Yb element; the second film layer 620 is the second electron injection layer EIL2, including Yb element; and the third film layer 630 is the second electrode CE, including Mg:Ag alloy and Yb element.

Since the work function of the metal in the third film layer 630 is greater than the work function of the metal in the first film layer 610, the third film layer 630 and the first film layer 610 cooperate with each other to enhance the capability of electrons moving to the side of the second light-emitting layer proximate to the first electrode, improving the performance of the electron injection and transport in the light-emitting device.

Since the work function of the metal in the third film layer 630 is greater than the work function of the metal in the second film layer 620, the third film layer 630 and the second film layer 620 cooperate with each other to enhance the capability of electrons moving to the side of the second light-emitting layer proximate to the first electrode, improving the performance of the electron injection and transport in the light-emitting device.

In some examples, the second film layer 620 and the third film layer 630 are arranged next to each other, which can be understood that the second film layer 620 is in direct contact with the third film layer 630.

For example, the second film layer 620 is the second electron injection layer EIL2, including Yb element; and the third film layer 630 is the second electrode CE, including Mg:Ag alloy and Yb element.

Since the work function of the metal in the third film layer 630 is greater than the work function of the metal in the second film layer 620, and the third film layer 630 is in direct contact with the second film layer 620, the electron injection performance of the second film layer 620 may be improved, thereby improving the overall electron injection performance of the light-emitting device.

In some embodiments, a film layer having the first category metal includes at least two types of metals in total.

It can be understood that the film layer having the first category metal already at least includes one type of the first category metal, and the remaining metal therein may include the first category metal, or may include the second category metal, or may include both the first category metal and the second category metal.

For example, if the second electrode CE includes Mg element, the second electrode CE further includes at least one type of metal in addition to the Mg element. For example, the at least one type of metal may be Ag element, or Yb element, or Ag element and Yb element.

In the above embodiments, the film layer having the first category metal includes at least two types of metals, which may enhance the coordination between the work functions of different metals in the film layer, so as to improve the capability of injecting and transporting electrons of the film layer, thereby improving the overall electron injection performance of the light-emitting device.

In some examples, at least two film layers located on the side of the first light-emitting layer away from the first electrode in the light-emitting device each include a same type of metal.

For example, in the at least two film layers located on the side of the first light-emitting layer away from the first electrode in the light-emitting device, each film layer includes one type of metal, and at least two film layers each include the same type of metal. For example, the first electron transport layer ETL1 includes Li element, and the second electron transport layer ETL2 includes Li element.

For example, in the at least two film layers located on the side of the first light-emitting layer away from the first electrode in the light-emitting device, some film layers each include one type of metal and other film layers each include multiple types of metals. For example, the second electron injection layer EIL2 includes Yb element, and the second electrode CE includes Mg:Ag alloy and Yb element.

In the above embodiments, the at least two film layers located on the side of the first light-emitting layer away from the first electrode in the light-emitting device each include the same type of metal, which may simplify the coordination relationship between the work functions of multiple types of metals and reduce the manufacturing materials of the light-emitting device.

In some embodiments, the second electrode CE, the second electron injection layer EIL2 and the charge generation layer 300 collectively include at least three types of metals. An absolute value of work function of metal in the second electrode CE is greater than an absolute value of work function of metal in the second electron injection layer EIL2; and the absolute value of the work function of the metal in the second electrode CE is greater than an absolute value of work function of metal in the charge generation layer 300.

In some examples, metals included in the second electrode CE, the second electron injection layer EIL2, and the charge generation layer 300 are each different. For example, the second electrode includes silver (Ag) element, the second electron injection layer includes cesium (Cs) element, and the charge generation layer includes ytterbium (Yb) element.

In some examples, a same metal may be included in the second electrode CE, the second electron injection layer EIL2, and the charge generation layer 300. For example, the second electrode CE includes silver (Ag) element, magnesium (Mg) element, and ytterbium (Yb) element, the second electron injection layer EIL2 includes ytterbium (Yb) element, and the charge generation layer 300 includes ytterbium (Yb) element.

Here, an absolute value of work function of silver (Ag) element is greater than an absolute value of work function of cesium (Cs) element, and the absolute value of the work function of silver (Ag) element is greater than an absolute value of work function of ytterbium (Yb) element; and an absolute value of work function of magnesium (Mg) element is greater than the absolute value of the work function of the cesium (Cs) element, and the absolute value of the work function of magnesium (Mg) element is greater than an absolute value of work function of ytterbium (Yb) element.

In this way, the above two types of examples may realize that the absolute value of the work function of the metal in the second electrode CE is greater than the absolute value of the work function of the metal in the second electron injection layer EIL2; and the absolute value of the work function of the metal in the second electrode CE is greater than the absolute value of the work function of the metal in the charge generation layer 300.

The absolute value of the work function of the metal in the second electrode CE is greater than the absolute value of the work function of the metal in the second electron injection layer EIL2, electrons can be better injected from the second electrode CE into the second light-emitting layer of the second light-emitting unit 220 through the second electron injection layer EIL2, thus improving the electron injection capability of the second light-emitting unit 220. The absolute value of the work function of the metal in the second electrode CE is greater than the absolute value of the work function of the metal in the charge generation layer 300, electrons can be better injected from the second electrode CE into the first light-emitting layer of the first light-emitting unit 210 through the charge generation layer 300, thus improving the electron injection capability of the first light-emitting unit 210. In this way, the overall electron injection capability of the light-emitting device can be improved, thereby improving the light extraction efficiency of the light-emitting device and reducing the driving voltage required by the light-emitting device.

In some embodiments, the at least three types of metals include at least two types of the first category metal and at least one type of the second category metal.

By arranging at least two types of the first category metal and at least one type of the second category metal, a potential barrier height between the second electrode CE and the second electron injection layer EIL2 may be facilitated to be lowered, thereby improving the electron injection performance of the second electrode CE and the second electron injection layer EIL2, further improving the electron injection capability of the second light-emitting unit 220.

By arranging at least two types of the first category metal and at least one type of the second category metal, a potential barrier height between the second electrode CE and the charge generation layer 300 may be facilitated to be lowered, thereby improving the electron injection performance of the second electrode CE and the charge generation layer 300, further improving the electron injection capability of the first light-emitting unit 210.

For example, the absolute value of the work function of the metal in the second electrode CE can be flexibly adjusted by adjusting a ratio of the at least two types of the first category metal in the second electrode CE, thereby making the second electrode CE match to the second electron injection layer EIL2 and/or the charge generation layer 300, to improve the overall electron injection performance of the light-emitting device.

In some embodiments, the second electrode CE and the second electron injection layer EIL2 include at least two types of the first category metal, and the second electron injection layer EIL2 and the charge generation layer 300 each include at least one type of the second category metal.

For example, the second electrode includes copper (Cu) element and tin (Sn) element, the second electron injection layer includes cesium (Cs) element, and the charge generation layer includes ytterbium (Yb) element.

For example, the second electrode includes copper (Cu) element and aluminum (Al) element, the second electron injection layer includes cesium (Cs) element and lithium (Li) element, and the charge generation layer includes ytterbium (Yb) element.

In some embodiments, the second electrode CE includes two types of the first category metal, in which a ratio between volumes of the two types of the first category metal is in a range of 100:1 to 1:100. In this way, the absolute value of the work function of the metal in the second electrode CE can be accurately adjusted between absolute values of the work functions of the two types of the first category metal.

In some embodiments, the second electron injection layer EIL2 may include a fifth host material and a fifth doping material. The fifth host material is an electron injection material, and the fifth doping material is a material including the second category metal. The fifth doping material is doped in the fifth host material, enabling the second category metal to be doped in the electron injection material.

In some embodiments, the charge generation layer 300 may include a sixth host material and a sixth doping material. The sixth host material is a charge generation material, and the sixth doping material is a material including the second category metal. The sixth doping material is doped in the sixth host material, enabling the second category metal to be doped in the charge generation material.

In some embodiments, the charge generation layer 300 includes a first charge generation sub-layer 320 and a second charge generation sub-layer 310. The first charge generation sub-layer 320 is the N-type charge generation sub-layer, and the second charge generation sub-layer 310 is the P-type charge generation sub-layer. The N-type charge generation sub-layer 320 may include the second category metal.

In some embodiments, the N-type charge generation sub-layer 320 includes at least one type of the second category metal. In the N-type charge generation sub-layer 320, a proportion of a total volume of the second category metal to a volume of the N-type charge generation sub-layer 320 is less than or equal to 1%. In this way, less charge generation material may be consumed in the N-type charge generation sub-layer 320, and the overall electron injection performance of the light-emitting device may be improved.

If the proportion of the second category metal to the N-type charge generation sub-layer 320 is relatively high, it will easily lead to quenching of excitons. The proportion of the total volume of the second category metal to the volume of the N-type charge generation sub-layer 320 is limited to less than 1%, which may prevent exciton quenching on the basis of improving the electron transport performance of the N-type charge generation sub-layer 320, thereby improving the reliability of the light-emitting device.

In some examples, a dimension of the N-type charge generation sub-layer 310 in the first direction X may be in a range of 150 Å to 300 Å, such as 150 Å, 180 Å, 200 Å, 225 Å, 250 Å, 275 Å, or 300 Å.

In some embodiments, the second electrode CE has a stacked structure, including a first sub-layer and a second sub-layer located on a side of the first sub-layer. The first sub-layer includes the first category metal, and the second sub-layer includes the second category metal. For example, the first sub-layer of the second electrode is a Mg:Ag alloy layer, and the second sub-layer of the second electrode is a ytterbium Yb metal layer. For example, a thickness of the first sub-layer in the first direction X may be 14 nm, and a thickness of the second sub-layer in the first direction X may be in a range of 0.5 nm to 2 nm, such as 0.5 nm, 0.7 nm, 1 nm, 1.2 nm, 1.5 nm, 1.8 nm, or 2 nm.

In some embodiments, in the light-emitting device, a ratio of a total volume of the first category metal to a total volume of the second category metal is less than or equal to 20:1.

The absolute value of the work function of the first category metal is greater than the absolute value of the work function of the second category metal. That is, the electron transport characteristics in the first category metal are better than the electron transport characteristics in the second category metal. Therefore, in the light-emitting device, the total volume of the first category metal is greater than the total volume of the second category metal, so the overall electron transport performance of the light-emitting device may be improved.

In some embodiments, in the light-emitting device, a proportion of the total volume of the second category metal to the total volume of the first category metal and the second category metal as a whole is greater than or equal to 5%, so as to improve the electron transport characteristics in the light-emitting device.

In some examples, the light-emitting device includes ytterbium (Yb) element, silver (Ag) element, and magnesium (Mg) element, in this case, a proportion of a sum of a volume of the silver (Ag) element and a volume of the magnesium (Mg) element to a sum of a volume of the ytterbium (Yb) element, the volume of the silver (Ag) element and the volume of the magnesium (Mg) element is greater than or equal to 5%.

In some examples, in the light-emitting device, the proportion of the total volume of the second category metal to the total volume of the first category metal and the second category metal is in a range of 6% to 9%. For example, in the above examples, the proportion of the sum of the volume of the silver (Ag) element and the volume of the magnesium (Mg) element to the sum of the volume of the ytterbium (Yb) element, the volume of the silver (Ag) element and the volume of the magnesium (Mg) element is in the range of 6% to 9%.

The first category metal has good light transmittance, and the proportion of the total of the second category metal to the first category metal and the second category metal as a whole is in the range of 6% to 9%, which may make the light-emitting device have a relatively high light transmittance, while enabling the light-emitting device to have good electron transport performance.

In some examples, the N-type charge generation sub-layer 320 and the second electron injection layer EIL2 each include Yb element, and the second electrode CE includes Mg:Ag alloy and Yb element. In the light-emitting device, the proportion of the total volume of the second category metal to the total volume of the first category metal and the second category metal as a whole is in the range of 6% to 9%, which may make the overall light transmittance of the second electron injection layer EIL2 and the second electrode CE greater than or equal to 50%.

In some embodiments, at least one type of at least three types of metals is both a non-alkaline earth metal and a non-alkali metal, which can be understood that the at least one type of the at least three types of metals is neither an alkaline earth metal nor an alkali metal.

For example, two types of metals are each both a non-alkaline earth metal and a non-alkali metal, and the other type of metal is an alkaline earth metal. As another example, one type of metal is both a non-alkaline earth metal and a non-alkali metal, another one type of metal is an alkaline earth metal, and yet another one type of metal is an alkali metal.

An absolute value of the work function of alkaline earth metals and alkali metals is relatively high, so the at least one type of the at least three types of metals is both a non-alkaline earth metal and a non-alkali metal. It can be understood that the at least three types of metals include at least one type of metal with work function of a relatively low absolute value, such as the second category metal.

In some examples, a proportion of the metal in the at least three types of metals that is both the non-alkaline earth metal and the non-alkali metal to the at least three types of metals is greater than or equal to 5%, which may improve the electron transport characteristics in the light-emitting device.

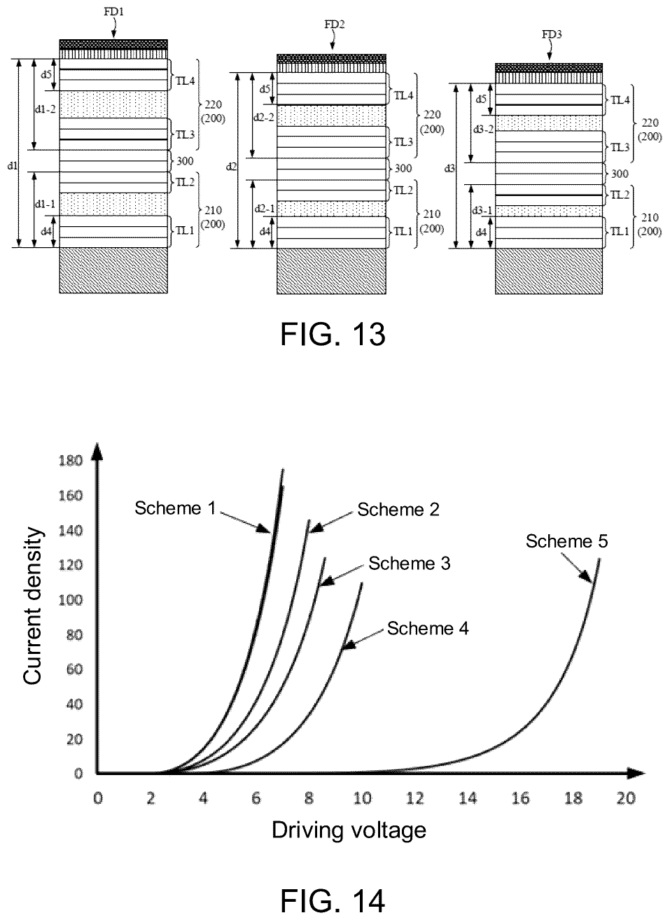

As shown in FIG. 13, in some embodiments, an absolute value of a difference between a dimension d4 of the first transport layer TL1 in the first direction X and a dimension d5 of the fourth transport layer TL4 in the first direction X is less than 15 nm.

It can be understood that an absolute value of a difference between a distance spaced between the first light-emitting layer and the first electrode and a distance spaced between the second light-emitting layer and the second electrode is less than 15 nm.

In some examples, the first transport layer includes the first hole injection layer HIL1, the first hole transport layer HTL1 and the first exciton blocking layer BL1, and the fourth transport layer TL4 includes the second electron injection layer EIL2, the second electron transport layer ETL2 and the third exciton blocking layer BL3. An absolute value of a difference between a sum of a dimension of the first hole injection layer HIL1 in the first direction X, a dimension of the first hole transport layer HTL1 in the first direction X and a dimension of the first exciton blocking layer BL1 in the first direction X, and a sum of a dimension of the second electron injection layer EIL2 in the first direction X, a dimension of the second electron transport layer ETL2 in the first direction X and a dimension of the third exciton blocking layer BL3 in the first direction X is less than 15 nm.

In some examples, the dimension d4 of the first transport layer TL1 in the first direction X is greater than the dimension d5 of the fourth transport layer TL4 in the first direction X. In some other examples, the dimension d4 of the first transport layer TL1 in the first direction X is less than the dimension d5 of the fourth transport layer TL4 in the first direction X.

By designing the absolute value of the difference between the dimension d4 of the first transport layer TL1 in the first direction X and the dimension d5 of the fourth transport layer TL4 in the first direction X to be less than 15 nm, the uniformity of the first transport layer TL1 in the first direction X and the fourth transport layer TL4 may be improved, so as to increase the matching degree between the light emitted by the first light-emitting unit 210 and the light emitted by the second light-emitting unit 220, thereby improving the overall light extraction efficiency of the light-emitting device.

The smaller the absolute value of the difference between the dimension d4 of the first transport layer TL1 in the first direction X and the dimension d5 of the fourth transport layer TL4 in the first direction X, the higher the matching degree between the light emitted by the first light-emitting unit 210 and the light emitted by the second light-emitting unit 220. Therefore, the absolute value of the difference between the dimension d4 of the first transport layer TL1 in the first direction X and the dimension d5 of the fourth transport layer TL4 in the first direction X may be in a range of 0 nm to 15 nm, such as 0 nm, 2 nm, 4 nm, 5 nm, 7 nm, 10 nm, 12 nm, 14 nm, or 15 nm.

As shown in FIG. 13, in some embodiments, a dimension of the second light-emitting unit 220 in the first direction X is greater than a dimension of the first light-emitting unit 210 in the first direction X. The dimension of the second light-emitting unit 220 in the first direction X may refer to a distance between the second electrode CE and the charge generation layer 300 in the first direction X. The dimension of the first light-emitting unit 210 in the first direction X may refer to a distance between the first electrode AE and the charge generation layer 300 in the first direction X. Therefore, it can be understood that the distance between the first electrode AE and the charge generation layer 300 in the first direction X is less than the distance between the second electrode CE and the charge generation layer 300 in the first direction X.

For example, the dimension of the second light-emitting unit 220 in the first direction X may refer to a sum of a dimension of the third transport layer TL3 in the first direction X, a dimension of the second light-emitting layer in the first direction X and a dimension of the fourth transport layer TL4 in the first direction X. For example, the dimension of the second light-emitting unit 220 in the first direction X includes a sum of a dimension of the second hole injection layer HIL2 in the first direction X, a dimension of the second hole transport layer HTL2 in the first direction X, a dimension of the second exciton blocking layer BL2 in the first direction X, a dimension of the second light-emitting layer in the first direction X, a dimension of the third exciton blocking layer BL3 in the first direction X, a dimension of the second electron transport layer ETL2 in the first direction X, and a dimension of the second electron injection layer EIL2 in the first direction X.

For example, the dimension of the first light-emitting unit 210 in the first direction X may refer to a sum of a dimension of the first transport layer TL1 in the first direction X, a dimension of the first light-emitting layer in the first direction X and a dimension of the second transport layer TL2 in the first direction X. For example, the dimension of the first light-emitting unit 210 in the first direction X includes a sum of a dimension of the first hole injection layer HIL1 in the first direction X, a dimension of the first hole transport layer HTL1 in the first direction X, a dimension of the first exciton blocking layer BL1 in the first direction X, a dimension of the first light-emitting layer in the first direction X, a dimension of the first electron transport layer ETL1 in the first direction X, and a dimension of the first electron injection layer EIL1 in the first direction X.

For example, in the first light-emitting opening K1, a dimension d1-2 of a second light-emitting unit 220 in the first direction X is greater than a dimension d1-1 of a first light-emitting unit 210 in the first direction X. As another example, in the second light-emitting opening K2, a dimension d2-2 of a second light-emitting unit 220 in the first direction X is greater than a dimension d2-1 of a first light-emitting unit 210 in the first direction X. As yet another example, in the third light-emitting opening K3, a dimension d3-2 of a second light-emitting unit 220 in the first direction X is greater than a dimension d3-1 of a first light-emitting unit 210 in the first direction X.

In some examples, a proportion of the dimension of the first light-emitting unit 210 in the first direction X to the dimension of the first light-emitting unit 210 and the second light-emitting unit 220 as a whole in the first direction X is in a range of 20% to 40%. It can be understood that a proportion of an optical path of the first light-emitting unit 210 to an optical path of the first light-emitting unit 210 and the second light-emitting unit 220 as a whole is in a range of 20% to 40%, such as 20%, 23%, 25%, 27%, 29%, 30%, 32%, 34%, 37%, 38%, or 40%.

In some examples, a proportion of the dimension of the second light-emitting unit 220 in the first direction X to a dimension of the first light-emitting unit 210 and the second light-emitting unit 220 as a whole in the first direction X is in a range of 55% to 80%. It can be understood that a proportion of an optical path of the second light-emitting unit 220 to an optical path of the first light-emitting unit 210 and the second light-emitting unit 220 as a whole is in a range of 55% to 80%, such as 55%, 58%, 59%, 60%, 61%, 63%, 66%, 68%, 70%, 71%, 75%, or 80%.

For example, in the first light-emitting opening, a proportion of a dimension d1-1 of a first light-emitting unit 210 in the first direction X to a dimension d1 of the first light-emitting unit 210 and a second light-emitting unit 220 as a whole in the first direction X is 34%; and in the first light-emitting opening, a proportion of a dimension d1-2 of the second light-emitting unit 220 in the first direction X to the dimension d1 of the first light-emitting unit 210 and the second light-emitting unit 220 as a whole in the first direction X is 66%. As another example, in the second light-emitting opening, a proportion of a dimension d2-1 of a first light-emitting unit 210 in the first direction X to a dimension d2 of the first light-emitting unit 210 and a second light-emitting unit 220 as a whole in the first direction X is 32%; and in the second light-emitting opening, a proportion of a dimension d2-2 of the second light-emitting unit 220 in the first direction X to the dimension d2 of the first light-emitting unit 210 and the second light-emitting unit 220 as a whole in the first direction X is 68%. As yet another example, in the third light-emitting opening, a proportion of a dimension d3-1 of a first light-emitting unit 210 in the first direction X to a dimension d3 of the first light-emitting unit 210 and a second light-emitting unit 220 as a whole in the first direction X is 29%; and in the third light-emitting opening, a proportion of a dimension d3-2 of the second light-emitting unit 220 in the first direction X to the dimension d3 of the first light-emitting unit 210 and the second light-emitting unit 220 as a whole in the first direction X is 71%.

In some examples, the proportion of the dimension of the first light-emitting unit 210 in the first direction X to the dimension of the first light-emitting unit 210 and the second light-emitting unit 220 as a whole in the first direction X is at least 20%; and the proportion of the dimension of the second light-emitting unit 220 in the first direction X to the dimension of the first light-emitting unit 210 and the second light-emitting unit 220 as a whole in the first direction X is at most 80%. That is, a ratio of the dimension of the second light-emitting unit 220 in the first direction X to the dimension of the first light-emitting unit 210 in the first direction X is 4.

In some other examples, the proportion of the dimension of the first light-emitting unit 210 in the first direction X to the dimension of the first light-emitting unit 210 and the second light-emitting unit 220 as a whole in the first direction X is at most 40%; and the proportion of the dimension of the second light-emitting unit 220 in the first direction X to the dimension of the first light-emitting unit 210 and the second light-emitting unit 220 as a whole in the first direction X is at least 55%. That is, a ratio of the dimension of the second light-emitting unit 220 in the first direction X to the dimension of the first light-emitting unit 210 in the first direction X is 1.375.

Based on the above two types of examples, the ratio of the dimension of the second light-emitting unit 220 in the first direction X to the dimension of the first light-emitting unit 210 in the first direction X can be determined to be within a range of 1.375 to 4.

In some embodiments, an opening area of the first light-emitting opening K1 is less than an opening area of the second light-emitting opening K2, and the opening area of the second light-emitting opening K2 is less than an opening area of the third light-emitting opening K3. Moreover, a wavelength of light emitted by the first light-emitting unit 210 in the first light-emitting opening K1 is greater than a wavelength of light emitted by the first light-emitting unit 210 in the second light-emitting opening K2, and the wavelength of the light emitted by the first light-emitting unit 210 in the second light-emitting opening K2 is greater than a wavelength of light emitted by the first light-emitting unit 210 in the third light-emitting opening K3.

In some examples, the light-emitting device in the first light-emitting opening K1 is a red light-emitting device, the light-emitting device in the second light-emitting opening K2 is a green light-emitting device, and the light-emitting device in the third light-emitting opening K3 is a blue light-emitting device. The wavelength of the light emitted by the first light-emitting unit 210 in the first light-emitting opening K1 may be in a range of 650 nm to 700 nm, the wavelength of the light emitted by the first light-emitting unit 210 in the second light-emitting opening K2 may be in a range of 510 nm to 540 nm, and the wavelength of the light emitted by the first light-emitting unit 210 in the third light-emitting opening K3 may be in a range of 460 nm to 470 nm.

In some embodiments, the opening area of the first light-emitting opening K1 is less than the opening area of the second light-emitting opening K2, and the opening area of the second light-emitting opening K2 is less than the opening area of the third light-emitting opening K3. Moreover, a wavelength of light emitted by the second light-emitting unit 220 in the first light-emitting opening K1 is greater than a wavelength of light emitted by the second light-emitting unit 220 in the second light-emitting opening K2, and the wavelength of the light emitted by the second light-emitting unit 220 in the second light-emitting opening K2 is greater than a wavelength of light emitted by the second light-emitting unit 220 in the third light-emitting opening K3.

In some examples, the light-emitting device in the first light-emitting opening K1 is a red light-emitting device, the light-emitting device in the second light-emitting opening K2 is a green light-emitting device, and the light-emitting device in the third light-emitting opening K3 is a blue light-emitting device. The wavelength of the light emitted by the second light-emitting unit 220 in the first light-emitting opening K1 may be in the range of 650 nm to 700 nm, the wavelength of the light emitted by the second light-emitting unit 220 in the second light-emitting opening K2 may be in the range of 510 nm to 540 nm, and the wavelength of the light emitted by the second light-emitting unit 220 in the third light-emitting opening K3 may be in the range of 460 nm to 470 nm.

Since the light extraction efficiency of a blue luminescent material is lower than the light extraction efficiency of a red luminescent material and a green luminescent material, by increasing the opening area of the third light-emitting opening K3 corresponding to the blue luminescent material, the third light-emitting opening K3 can emit more blue light to balance red light and green light to improve the display effect of the display panel. In addition, the stability of the blue luminescent material is worse than the stability of the red luminescent material, so under high current density, a light-emitting device of the blue luminescent material decays faster. Increasing the opening area of the third light-emitting opening can reduce the current density under the same voltage, and delay the decay of the light-emitting device, thereby improving the efficiency and lifetime of the light-emitting device.

As shown in FIG. 13, in some embodiments, for the dimension d1-1 of the first light-emitting unit 210 in the first light-emitting opening K1 in the first direction X, the dimension d2-1 of the first light-emitting unit 210 in the second light-emitting opening K2 in the first direction X, and the dimension d3-1 of the first light-emitting unit 210 in the third light-emitting opening K3 in the first direction X, at least two of the three are not equal.

It will be noted that a dimension of a first light-emitting unit 210 in each of different light-emitting openings in the first direction X can be understood as an optical path of light in this light-emitting opening between the first electrode and the second light-emitting unit 220 therein.

By arranging optical paths with different dimensions in the first direction X, it is possible to facilitate different wavelengths of light to achieve respective optimal light extraction efficiency, thereby improving the light extraction efficiency of the display panel.

In some examples, the dimension d1-1 of the first light-emitting unit 210 in the first light-emitting opening K1 in the first direction X is greater or less than the dimension d2-1 of the first light-emitting unit 210 in the second light-emitting opening K2 in the first direction X; and the dimension d2-1 of the first light-emitting unit 210 in the second light-emitting opening K2 in the first direction X is equal to the dimension d3-1 of the first light-emitting unit 210 in the third light-emitting opening K3 in the first direction X.

In some examples, the dimension d1-1 of the first light-emitting unit 210 in the first light-emitting opening K1 in the first direction X is equal to the dimension d2-1 of the first light-emitting unit 210 in the second light-emitting opening K2 in the first direction X; and the dimension d2-1 of the first light-emitting unit 210 in the second light-emitting opening K2 in the first direction X is greater or less than the dimension d3-1 of the first light-emitting unit 210 in the third light-emitting opening K3 in the first direction X.

In some examples, the dimension d1-1 of the first light-emitting unit 210 in the first light-emitting opening K1 in the first direction X is greater than the dimension d2-1 of the first light-emitting unit 210 in the second light-emitting opening K2 in the first direction X; and the dimension d2-1 of the first light-emitting unit 210 in the second light-emitting opening K2 in the first direction X is greater than the dimension d3-1 of the first light-emitting unit 210 in the third light-emitting opening K3 in the first direction X.

In some examples, the display panel 100 is a top-emission display panel, and the first electrode is ITO/Ag/ITO. The optical path of the light in the light-emitting opening between the first electrode and the second light-emitting unit 220 may further include a dimension of the ITO in the first direction X. Since the light-emitting openings are each provided with a first electrode, the magnitude relationship between the optical paths of light in different light-emitting openings between the first electrode and the second light-emitting unit 220 will not be changed.

After creative efforts, the inventors of the present disclosure have discovered that the larger the wavelength, the larger the optical path required to achieve optimal light extraction efficiency. Therefore, in the above examples, the light in the first light-emitting opening K1, the second light-emitting opening K2 and the third light-emitting opening K3 may all achieve optimal light extraction efficiency, thereby improving the light extraction efficiency of the display panel.

In some embodiments, for the dimension d1-2 of the second light-emitting unit 220 in the first light-emitting opening K1 in the first direction X, the dimension d2-2 of the second light-emitting unit 220 in the second light-emitting opening K2 in the first direction X, and the dimension d3-2 of the second light-emitting unit 220 in the third light-emitting opening K3 in the first direction X, at least two of the three are not equal.

It will be noted that a dimension of a second light-emitting unit 220 in each of different light-emitting openings in the first direction X can be understood as an optical path of light in this light-emitting opening between the first light-emitting unit 210 and the second electrode therein.

By arranging optical paths with different dimensions in the first direction X, it is possible to facilitate different wavelengths of light to achieve respective optimal light extraction efficiency, thereby improving the light extraction efficiency of the display panel.

In some examples, the dimension d1-2 of the second light-emitting unit 220 in the first light-emitting opening K1 in the first direction X is greater or less than the dimension d2-2 of the second light-emitting unit 220 in the second light-emitting opening K2 in the first direction X; and the dimension d2-2 of the second light-emitting unit 220 in the second light-emitting opening K2 in the first direction X is equal to the dimension d3-2 of the second light-emitting unit 220 in the third light-emitting opening K3 in the first direction X.

In some examples, the dimension d1-2 of the second light-emitting unit 220 in the first light-emitting opening K1 in the first direction X is equal to the dimension d2-2 of the second light-emitting unit 220 in the second light-emitting opening K2 in the first direction X; and the dimension d2-2 of the second light-emitting unit 220 in the second light-emitting opening K2 in the first direction X is greater or less than the dimension d3-2 of the second light-emitting unit 220 in the third light-emitting opening K3 in the first direction X.

In some examples, the dimension d1-2 of the second light-emitting unit 220 in the first light-emitting opening K1 in the first direction X is greater than the dimension d2-2 of the second light-emitting unit 220 in the second light-emitting opening K2 in the first direction X; and the dimension d2-2 of the second light-emitting unit 220 in the second light-emitting opening K2 in the first direction X is greater than the dimension d3-2 of the second light-emitting unit 220 in the third light-emitting opening K3 in the first direction X.

Since the larger the wavelength, the larger the optical path required to achieve optimal light extraction efficiency, in the above examples, the light in the first light-emitting opening K1, the second light-emitting opening K2 and the third light-emitting opening K3 may all achieve optimal light extraction efficiency, thereby improving the light extraction efficiency of the display panel.

In some embodiments, for the dimension d1 of the first light-emitting unit 210 and the second light-emitting unit 220 as a whole in the first light-emitting opening K1 in the first direction X, the dimension d2 of the first light-emitting unit 210 and the second light-emitting unit 220 as a whole in the second light-emitting opening K2 in the first direction X, and the dimension d3 of the first light-emitting unit 210 and the second light-emitting unit 220 as a whole in the third light-emitting opening K3 in the first direction X, at least two of the three are not equal.

It will be noted that a dimension of a first light-emitting unit 210 and a second light-emitting unit 220 as a whole in each of different light-emitting openings in the first direction X can be understood as a dimension of a microcavity structure corresponding to light in this light-emitting opening in the first direction X.

By arranging microcavity structures with different dimensions in the first direction X to act on different wavelengths of light, it is possible to facilitate the different wavelengths of light to achieve respective optimal light extraction efficiency, thereby improving the light extraction efficiency of the display panel.

In some examples, the dimension d1 of the first light-emitting unit 210 and the second light-emitting unit 220 as a whole in the first light-emitting opening K1 in the first direction X is greater or less than the dimension d2 of the first light-emitting unit 210 and the second light-emitting unit 220 as a whole in the second light-emitting opening K2 in the first direction X; and the dimension d2 of the first light-emitting unit 210 and the second light-emitting unit 220 as a whole in the second light-emitting opening K2 in the first direction X is equal to the dimension d3 of the first light-emitting unit 210 and the second light-emitting unit 220 as a whole in the third light-emitting opening K3 in the first direction X.

In some examples, the dimension d1 of the first light-emitting unit 210 and the second light-emitting unit 220 as a whole in the first light-emitting opening K1 in the first direction X is equal to the dimension d2 of the first light-emitting unit 210 and the second light-emitting unit 220 as a whole in the second light-emitting opening K2 in the first direction X; and the dimension d2 of the first light-emitting unit 210 and the second light-emitting unit 220 as a whole in the second light-emitting opening K2 in the first direction X is greater or less than the dimension d3 of the first light-emitting unit 210 and the second light-emitting unit 220 as a whole in the third light-emitting opening K3 in the first direction X.

In some examples, the dimension d1 of the first light-emitting unit 210 and the second light-emitting unit 220 as a whole in the first light-emitting opening K1 in the first direction X is greater than the dimension d2 of the first light-emitting unit 210 and the second light-emitting unit 220 as a whole in the second light-emitting opening K2 in the first direction X; and the dimension d3 of the first light-emitting unit 210 and the second light-emitting unit 220 as a whole in the second light-emitting opening K2 in the first direction X is greater than the dimension d2 of the first light-emitting unit 210 and the second light-emitting unit 220 as a whole in the third light-emitting opening K3 in the first direction X.

In some examples, the dimension d1 of the first light-emitting unit 210 and the second light-emitting unit 220 as a whole in the first light-emitting opening K1 in the first direction X is greater than the dimension d2 of the first light-emitting unit 210 and the second light-emitting unit 220 as a whole in the second light-emitting opening K2 in the first direction X; and the dimension d2 of the first light-emitting unit 210 and the second light-emitting unit 220 as a whole in the second light-emitting opening K2 in the first direction X is greater than the dimension d3 of the first light-emitting unit 210 and the second light-emitting unit 220 as a whole in the third light-emitting opening K3 in the first direction X.

Since the larger the wavelength, the larger the optical path required to achieve optimal light extraction efficiency, and a dimension of the microcavity structure in the first direction X is positively correlated with the optical path, in the above examples, the light in the first light-emitting opening K1, the second light-emitting opening K2 and the third light-emitting opening K3 may all achieve optimal light extraction efficiency, thereby improving the light extraction efficiency of the display panel.

In some embodiments, for a proportion of the dimension of the first light-emitting unit 210 to the dimension of the first light-emitting unit 210 and the second light-emitting unit 220 as a whole in the first light-emitting opening K1 in the first direction X, a proportion of the dimension of the first light-emitting unit 210 to the dimension of the first light-emitting unit 210 and the second light-emitting unit 220 as a whole in the second light-emitting opening K2 in the first direction X, and a proportion of the dimension of the first light-emitting unit 210 to the dimension of the first light-emitting unit 210 and the second light-emitting unit 220 as a whole in the third light-emitting opening K3 in the first direction X, at least two of the three are not equal.

That is, for a proportion of the dimension d1-1 of the first light-emitting unit 210 in the first light-emitting opening K1 in the first direction X to the dimension d1 of the first light-emitting unit 210 and the second light-emitting unit 220 as a whole in the first light-emitting opening K1 in the first direction X, a proportion of the dimension d2-1 of the first light-emitting unit 210 in the second light-emitting opening K2 in the first direction X to the dimension d2 of the first light-emitting unit 210 and the second light-emitting unit 220 as a whole in the second light-emitting opening K2 in the first direction X, and a proportion of the dimension d3-1 of the first light-emitting unit 210 in the third light-emitting opening K3 in the first direction X to the dimension d3 of the first light-emitting unit 210 and the second light-emitting unit 220 as a whole in the third light-emitting opening K3 in the first direction X, at least two of the three are not equal.

It will be noted that the larger the proportion of the dimension of the first light-emitting unit 210 to the dimension of the first light-emitting unit 210 and the second light-emitting unit 220 as a whole in the first direction X, it is to be understood that the optical path of the light in the light-emitting opening between the first electrode and the second light-emitting unit 220 is larger.

By designing different proportions of the dimension of the first light-emitting unit 210 to the dimension of the first light-emitting unit 210 and the second light-emitting unit 220 as a whole in different light-emitting openings in the first direction X, it is possible to facilitate the different wavelengths of light to achieve respective optimal light extraction efficiency, thereby improving the light extraction efficiency of the display panel.

In some examples, the proportion of the dimension d1-1 of the first light-emitting unit 210 in the first light-emitting opening K1 in the first direction X to the dimension d1 of the first light-emitting unit 210 and the second light-emitting unit 220 as a whole in the first light-emitting opening K1 in the first direction X is greater or less than the proportion of the dimension d2-1 of the first light-emitting unit 210 in the second light-emitting opening K2 in the first direction X to the dimension d2 of the first light-emitting unit 210 and the second light-emitting unit 220 as a whole in the second light-emitting opening K2 in the first direction X; and the proportion of the dimension d2-1 of the first light-emitting unit 210 in the second light-emitting opening K2 in the first direction X to the dimension d2 of the first light-emitting unit 210 and the second light-emitting unit 220 as a whole in the second light-emitting opening K2 in the first direction X is equal to the proportion of the dimension d3-1 of the first light-emitting unit 210 in the third light-emitting opening K3 in the first direction X to the dimension d3 of the first light-emitting unit 210 and the second light-emitting unit 220 as a whole in the third light-emitting opening K3 in the first direction X.

In some examples, the proportion of the dimension d1-1 of the first light-emitting unit 210 in the first light-emitting opening K1 in the first direction X to the dimension d1 of the first light-emitting unit 210 and the second light-emitting unit 220 as a whole in the first light-emitting opening K1 in the first direction X is equal to the proportion of the dimension d2-1 of the first light-emitting unit 210 in the second light-emitting opening K2 in the first direction X to the dimension d2 of the first light-emitting unit 210 and the second light-emitting unit 220 as a whole in the second light-emitting opening K2 in the first direction X; and the proportion of the dimension d2-1 of the first light-emitting unit 210 in the second light-emitting opening K2 in the first direction X to the dimension d2 of the first light-emitting unit 210 and the second light-emitting unit 220 as a whole in the second light-emitting opening K2 in the first direction X is greater or less than the proportion of the dimension d3-1 of the first light-emitting unit 210 in the third light-emitting opening K3 in the first direction X to the dimension d3 of the first light-emitting unit 210 and the second light-emitting unit 220 as a whole in the third light-emitting opening K3 in the first direction X.

In some examples, the proportion of the dimension d1-1 of the first light-emitting unit 210 in the first light-emitting opening K1 in the first direction X to the dimension d1 of the first light-emitting unit 210 and the second light-emitting unit 220 as a whole in the first light-emitting opening K1 in the first direction X is greater than the proportion of the dimension d2-1 of the first light-emitting unit 210 in the second light-emitting opening K2 in the first direction X to the dimension d2 of the first light-emitting unit 210 and the second light-emitting unit 220 as a whole in the second light-emitting opening K2 in the first direction X; and the proportion of the dimension d2-1 of the first light-emitting unit 210 in the second light-emitting opening K2 in the first direction X to the dimension d2 of the first light-emitting unit 210 and the second light-emitting unit 220 as a whole in the second light-emitting opening K2 in the first direction X is greater than the proportion of the dimension d3-1 of the first light-emitting unit 210 in the third light-emitting opening K3 in the first direction X to the dimension d3 of the first light-emitting unit 210 and the second light-emitting unit 220 as a whole in the third light-emitting opening K3 in the first direction X.

For example, the proportion of the dimension d1-1 of the first light-emitting unit 210 in the first light-emitting opening K1 in the first direction X to the dimension d1 of the first light-emitting unit 210 and the second light-emitting unit 220 as a whole in the first light-emitting opening K1 in the first direction X is 34%; the proportion of the dimension d2-1 of the first light-emitting unit 210 in the second light-emitting opening K2 in the first direction X to the dimension d2 of the first light-emitting unit 210 and the second light-emitting unit 220 as a whole in the second light-emitting opening K2 in the first direction X is 32%; and the proportion of the dimension d3-1 of the first light-emitting unit 210 in the third light-emitting opening K3 in the first direction X to the dimension d3 of the first light-emitting unit 210 and the second light-emitting unit 220 as a whole in the third light-emitting opening K3 in the first direction X is 29%.

Since the larger the wavelength, the larger the optical path required to achieve optimal light extraction efficiency, in the above examples, the light in the first light-emitting opening K1, the second light-emitting opening K2 and the third light-emitting opening K3 may all achieve optimal light extraction efficiency, thereby improving the light extraction efficiency of the display panel.

In some embodiments, for a proportion of the dimension of the second light-emitting unit 220 to the dimension of the first light-emitting unit 210 and the second light-emitting unit 220 as a whole in the first light-emitting opening K1 in the first direction X, a proportion of the dimension of the second light-emitting unit 220 to the dimension of the first light-emitting unit 210 and the second light-emitting unit 220 as a whole in the second light-emitting opening K2 in the first direction X, and a proportion of the dimension of the second light-emitting unit 220 to the dimension of the first light-emitting unit 210 and the second light-emitting unit 220 as a whole in the third light-emitting opening K3 in the first direction X, at least two of the three are not equal.

That is, for the proportion of the dimension d1-2 of the second light-emitting unit 220 in the first light-emitting opening K1 in the first direction X to the dimension d1 of the first light-emitting unit 210 and the second light-emitting unit 220 as a whole in the first light-emitting opening K1 in the first direction X, the proportion of the dimension d2-2 of the second light-emitting unit 220 in the second light-emitting opening K2 in the first direction X to the dimension d2 of the first light-emitting unit 210 and the second light-emitting unit 220 as a whole in the second light-emitting opening K2 in the first direction X, and the proportion of the dimension d3-2 of the second light-emitting unit 220 in the third light-emitting opening K3 in the first direction X to the dimension d3 of the first light-emitting unit 210 and the second light-emitting unit 220 as a whole in the third light-emitting opening K3 in the first direction X, at least two of the three are not equal.

In some examples, the proportion of the dimension d1-2 of the second light-emitting unit 220 in the first light-emitting opening K1 in the first direction X to the dimension d1 of the first light-emitting unit 210 and the second light-emitting unit 220 as a whole in the first light-emitting opening K1 in the first direction X is greater or less than the proportion of the dimension d2-2 of the second light-emitting unit 220 in the second light-emitting opening K2 in the first direction X to the dimension d2 of the first light-emitting unit 210 and the second light-emitting unit 220 as a whole in the second light-emitting opening K2 in the first direction X; and the proportion of the dimension d2-2 of the second light-emitting unit 220 in the second light-emitting opening K2 in the first direction X to the dimension d2 of the first light-emitting unit 210 and the second light-emitting unit 220 as a whole in the second light-emitting opening K2 in the first direction X is equal to the proportion of the dimension d3-2 of the second light-emitting unit 220 in the third light-emitting opening K3 in the first direction X to the dimension d3 of the first light-emitting unit 210 and the second light-emitting unit 220 as a whole in the third light-emitting opening K3 in the first direction X.

In some examples, the proportion of the dimension d1-2 of the second light-emitting unit 220 in the first light-emitting opening K1 in the first direction X to the dimension d1 of the first light-emitting unit 210 and the second light-emitting unit 220 as a whole in the first light-emitting opening K1 in the first direction X is equal to the proportion of the dimension d2-2 of the second light-emitting unit 220 in the second light-emitting opening K2 in the first direction X to the dimension d2 of the first light-emitting unit 210 and the second light-emitting unit 220 as a whole in the second light-emitting opening K2 in the first direction X; and the proportion of the dimension d2-2 of the second light-emitting unit 220 in the second light-emitting opening K2 in the first direction X to the dimension d2 of the first light-emitting unit 210 and the second light-emitting unit 220 as a whole in the second light-emitting opening K2 in the first direction X is greater or less than the proportion of the dimension d3-2 of the second light-emitting unit 220 in the third light-emitting opening K3 in the first direction X to the dimension d3 of the first light-emitting unit 210 and the second light-emitting unit 220 as a whole in the third light-emitting opening K3 in the first direction X.

In some examples, the proportion of the dimension d1-2 of the second light-emitting unit 220 in the first light-emitting opening K1 in the first direction X to the dimension d1 of the first light-emitting unit 210 and the second light-emitting unit 220 as a whole in the first light-emitting opening K1 in the first direction X is less than the proportion of the dimension d2-2 of the second light-emitting unit 220 in the second light-emitting opening K2 in the first direction X to the dimension d2 of the first light-emitting unit 210 and the second light-emitting unit 220 as a whole in the second light-emitting opening K2 in the first direction X; and the proportion of the dimension d2-2 of the second light-emitting unit 220 in the second light-emitting opening K2 in the first direction X to the dimension d2 of the first light-emitting unit 210 and the second light-emitting unit 220 as a whole in the second light-emitting opening K2 in the first direction X is less than the proportion of the dimension d3-2 of the second light-emitting unit 220 in the third light-emitting opening K3 in the first direction X to the dimension d3 of the first light-emitting unit 210 and the second light-emitting unit 220 as a whole in the third light-emitting opening K3 in the first direction X.

For example, the proportion of the dimension d1-2 of the second light-emitting unit 220 in the first light-emitting opening K1 in the first direction X to the dimension d1 of the first light-emitting unit 210 and the second light-emitting unit 220 as a whole in the first light-emitting opening K1 in the first direction X is 66%; the proportion of the dimension d2-2 of the second light-emitting unit 220 in the second light-emitting opening K2 in the first direction X to the dimension d2 of the first light-emitting unit 210 and the second light-emitting unit 220 as a whole in the second light-emitting opening K2 in the first direction X is 68%; and the proportion of the dimension d3-2 of the second light-emitting unit 220 in the third light-emitting opening K3 in the first direction X to the dimension d3 of the first light-emitting unit 210 and the second light-emitting unit 220 as a whole in the third light-emitting opening K3 in the first direction X is 71%.

In the above examples, the light in the first light-emitting opening K1, the second light-emitting opening K2 and the third light-emitting opening K3 may all achieve optimal light extraction efficiency, thereby improving the light extraction efficiency of the display panel.

As shown in FIG. 2, in some embodiments, the plurality of light-emitting openings includes at least one light-emitting opening unit KU. A light-emitting opening unit KU includes a first light-emitting opening K1, a second light-emitting opening K2, and a third light-emitting opening K3 which correspond to different colors.

A light-emitting opening unit KU corresponds to a pixel unit region PU, and the number of light-emitting openings in the light-emitting opening unit KU is equal to the number of sub-pixel regions in the pixel unit region. Multiple light-emitting openings in a light-emitting opening unit KU correspond one by one to multiple sub-pixel regions in a pixel unit region PU.

In some embodiments, in a light-emitting opening unit KU, for a total volume V1 of a light-emitting device in a first light-emitting opening K1, a total volume V2 of a light-emitting device in a second light-emitting opening K2, and a total volume V3 of a light-emitting device in a third light-emitting opening K3, at least two of the three are not equal.

Materials of light-emitting devices in different light-emitting openings are different, and the stability of different materials are different, for example, the materials have different tolerances and decay trends for current and voltage. By designing the light-emitting devices of different volumes in different light-emitting openings, the stability of the light-emitting devices can be improved purposefully, so that the stability of different light-emitting devices may achieve optimal stability.

A light-emitting opening unit KU may include one or more first light-emitting openings K1, one or more second light-emitting openings K2, and one or more third light-emitting openings K3.

In a case where a light-emitting opening unit KU includes one first light-emitting opening K1, the total volume V1 of the light-emitting device in the first light-emitting opening K1 refers to a volume of a light-emitting device in the one first light-emitting opening K1; and in a case where a light-emitting opening unit KU includes multiple first light-emitting openings K1, the total volume V1 of the light-emitting device in the first light-emitting opening K1 refers to a sum of volumes of light-emitting devices in all of the first light-emitting openings K1.

Similarly, the meaning of the total volume V2 of the light-emitting device in the second light-emitting opening K2 and the meaning of the total volume V3 of the light-emitting device in the third light-emitting opening K3 are essentially the same as the meaning of the total volume V1 of the light-emitting device in the first light-emitting opening K1, which will not be repeated here.

In some examples, the total volume V1 of the light-emitting device in the first light-emitting opening K1 is greater or less than the total volume V2 of the light-emitting device in the second light-emitting opening K2; and the total volume V2 of the light-emitting device in the second light-emitting opening K2 is equal to the total volume V3 of the light-emitting device in the third light-emitting opening K3.

In some examples, the total volume V1 of the light-emitting device in the first light-emitting opening K1 is equal to the total volume V2 of the light-emitting device in the second light-emitting opening K2; and the total volume V2 of the light-emitting device in the second light-emitting opening K2 is greater or less than the total volume V3 of the light-emitting device in the third light-emitting opening K3.

In some examples, the total volume V1 of the light-emitting device in the first light-emitting opening K1 is less than the total volume V2 of the light-emitting device in the second light-emitting opening K2; and the total volume V2 of the light-emitting device in the second light-emitting opening K2 is less than the total volume V3 of the light-emitting device in the third light-emitting opening K3.

Taking the light-emitting device in the third light-emitting opening as an example, the stability of the light-emitting device in the third light-emitting opening is relatively weak and decays faster under high current density. In the above examples, the volume of the light-emitting device in the third light-emitting opening is increased, so that the current density can be reduced under the same voltage, delaying the decay of the light-emitting device, and thereby improving the efficiency and lifetime of the light-emitting device.

In some embodiments, the total volume V2 of the light-emitting device in the second light-emitting opening K2 is greater than half of the total volume V1 of the light-emitting device in the first light-emitting opening K1. That is, a ratio of the total volume V2 of the light-emitting device in the second light-emitting opening K2 to the total volume V1 of the light-emitting device in the first light-emitting opening K1 is greater than 50%, such as 51%, 55%, 60%, 70%, 80%, 90%, 100%, 110%, or 120%.

In some embodiments, the total volume V3 of the light-emitting device in the third light-emitting opening K3 is greater than half of the total volume V1 of the light-emitting device in the first light-emitting opening K1. That is, a ratio of the total volume V3 of the light-emitting device in the third light-emitting opening K3 to the total volume V1 of the light-emitting device in the first light-emitting opening K1 is greater than 50%. For example, 51%, 55%, 60%, 70%, 80%, 90%, 100%, 110%, or 120%.

In some embodiments, in a light-emitting opening unit KU, the number of first light-emitting opening(s) K1, the number of second light-emitting opening(s) K2 and the number of third light-emitting opening(s) K3 are all equal. For example, a light-emitting opening unit KU includes one first light-emitting opening K1, one second light-emitting opening K2, and one third light-emitting opening K3.

In this case, the total volume V1 of the light-emitting device in the first light-emitting opening K1 may be greater than or equal to the total volume V2 of the light-emitting device in the second light-emitting opening K2; and the total volume V1 of the light-emitting device in the first light-emitting opening K1 may be greater than or equal to the total volume V3 of the light-emitting device in the third light-emitting opening K3.

In other words, the total volume V1 of the light-emitting device in the first light-emitting opening K1 is neither less than the total volume V2 of the light-emitting device in the second light-emitting opening K2, nor less than the total volume V3 of the light-emitting device in the third light-emitting opening K3.

In some examples, a ratio of the total volume V2 of the light-emitting device in the second light-emitting opening K2 to the total volume V1 of the light-emitting device in the first light-emitting opening K1 is in a range of 0.6 to 1, such as 0.6, 0.65, 0.7, 0.75, 0.8, 0.85, 0.9, 0.95, or 1.

In some examples, a ratio of the total volume V3 of the light-emitting device in the third light-emitting opening K3 to the total volume V1 of the light-emitting device in the first light-emitting opening K1 is in a range of 0.5 to 0.9, such as 0.5, 0.55, 0.6, 0.65, 0.7, 0.75, 0.8, 0.85, or 0.9.

In some embodiments, in a light-emitting opening unit KU, for the number of first light-emitting opening(s) K1, the number of second light-emitting opening(s) K2 and the number of third light-emitting opening(s) K3, at least two of the three are not equal. For example, a light-emitting opening unit KU includes one first light-emitting opening K1, two second light-emitting openings K2, and one third light-emitting opening K3.

In some examples, a ratio of the total volume V2 of the light-emitting device in the second light-emitting opening K2 to the total volume V1 of the light-emitting device in the first light-emitting opening K1 is in a range of 0.8 to 1.6, such as 0.8, 0.85, 0.9, 0.95, 1, 1.05, 1.1, 1.15, 1.2, 1.25, 1.3, 1.35, 1.4, 1.45, 1.5, 1.55, or 1.6.

The stability of the light-emitting device in the second light-emitting opening is worse than the stability of the light-emitting device in the first light-emitting opening. Under high current density, the light-emitting device in the second light-emitting opening decay faster. Therefore, it is necessary to increase the volume of the light-emitting device in the second light-emitting opening, so as to reduce the current density thereof under the same voltage, and delay the decay of the light-emitting device, thereby improving the efficiency and lifetime of the light-emitting device.

In some examples, the ratio of the total volume V3 of the light-emitting devices in the third light-emitting opening K3 to the total volume V1 of the light-emitting devices in the first light-emitting opening K1 is in the range of 1 to 2.3. For example, 1, 1.1, 1.2, 1.22, 1.3, 1.5, 1.8, 2, 2.1, or 2.3.

The stability of the light-emitting device in the third light-emitting opening is worse than the stability of the light-emitting device in the first light-emitting opening. Under high current density, the light-emitting device in the third light-emitting opening decays faster. Therefore, it is necessary to increase the volume of the light-emitting device in the third light-emitting opening, so as to reduce the current density thereof under the same voltage, and delay the decay of the light-emitting device, thereby improving the efficiency and lifetime of the light-emitting device.

In other words, the total volume V1 of the light-emitting device in the first light-emitting opening K1 is not greater than the total volume V3 of the light-emitting device in the third light-emitting opening K3.

As shown in FIG. 2, the light extraction layer CPL above-mentioned covers the light-emitting device layer LDL. For example, the light extraction layer CPL is directly located on the second electrode CE. The light extraction layer CPL can improve the light extraction efficiency of the light-emitting device layer LDL, since the light extraction layer CPL has a large refractive index and a small light absorption coefficient.

In some examples, a dimension of the light extraction layer CPL in the first direction X may be in a range of 50 nm to 80 nm. The refractive index of the light extraction layer CPL for light of a wavelength of 460 nm may be greater than or equal to 1.8, such as 1.8, 1.9, 2.0, or 2.1, which is not limited here.

As shown in FIG. 8, the encapsulation layer TFE is used to encapsulate the light-emitting device layer LDL and the light extraction layer CPL. In some embodiments, the encapsulation layer TFE may include a first encapsulation layer ENL1, a second encapsulation layer ENL2 and a third encapsulation layer ENL3 that are stacked in sequence. For example, the first encapsulation layer ENL1 and the third encapsulation layer ENL3 are made of an inorganic material. The inorganic material is at least one selected from silicon nitride, aluminum nitride, zirconium nitride, titanium nitride, hafnium nitride, tantalum nitride, silicon oxide, aluminum oxide, titanium oxide, tin oxide, cerium oxide, silicon oxynitride (SiON), or lithium fluoride. As another example, the second encapsulation layer ENL2 is made of an organic material. The organic material is at least one of acrylic resin, methacrylic resin, polyisoprene, vinyl resin, epoxy resin, polyurethane resin, cellulose resin, or perylene resin. The number of layers, materials and structure of the encapsulation layer TFE may be varied by those skilled in the art according to requirements, which are not limited in the present disclosure.

In order to verify the effect of metals with different absolute values of work functions on the electron injection characteristics of the light-emitting device, the present disclosure provides the following five experimental schemes for comparison, to demonstrate performance of the electron injection characteristic in the light-emitting device by detecting the current density of the second electrode in the light-emitting device, in which the higher the current density of the second electrode in the light-emitting device, the better the electron injection performance of the light-emitting device.

Scheme 1: the second electrode CE includes two types of the first category metal and one type of the second category metal, and the second electron injection layer EIL2 includes one type of the second category metal.

Scheme 2: the second electrode CE includes two types of the first category metal, and the second electron injection layer EIL2 includes one type of the second category metal.

Scheme 3: the second electrode CE includes two types of the first category metal and one type of the second category metal, and the second electron injection layer EIL2 does not include metal.

Scheme 4: the second electrode CE includes two types of the first category metal, and the second electron injection layer EIL2 does not include metal.

Scheme 5: the second electrode CE includes one type of the first category metal.

FIG. 14 shows the variation curves of the current density of the second electrode CE of the light-emitting device under different driving voltages under the five schemes. It can be found that in the order of Scheme 1 to Scheme 5, the current density of the second electrode is getting lower and lower under the same driving voltage. Scheme 1 to Scheme 4 can significantly improve the current density of the second electrode CE under low driving voltage compared with the traditional Scheme 5.

As shown in Table 1, a comparison between Scheme 1 and Scheme 2 shows that adding one type of the second category metal to the second electrode CE can further improve the light extraction efficiency of the light-emitting device and further reduce the driving voltage of the light-emitting device.

TABLE 1

| | | Second | | | |
|---|---|---|---|---|---|
| | | electron | Light | | |
| Scheme | Second | injection | extraction | Driving | Device |
| item | electrode | layer | efficiency | voltage | lifetime |
| Scheme 1 | Two types | One type | 185% | 200% | 230% |
| | of the | of the | | | |
| | first | second | | | |
| | metal | metal | | | |
| Scheme 2 | Two types of | One type | 200% | 160% | 235% |
| | the first | of the | | | |
| | metal and one | second | | | |
| | type of the | metal | | | |
| | second metal | | | | |

In summary, in the light-emitting device and the display panels provided by some embodiments of the present disclosure, at least three types of metals are added to the second electrode, the second electron injection layer and the charge generation layer, so that the absolute value of the work function of the metal in the second electrode is greater than the absolute value of the work function of the metal in the second electron injection layer, which enables electrons to be better injected from the second electrode through the second electron injection layer into the second light-emitting layer of the second light-emitting unit, improving the electron injection capability of the second light-emitting unit; and the absolute value of the work function of the metal in the second electrode is greater than the absolute value of the work function of the metal in the charge generation layer, which enables electrons to be better injected from the second electrode through the charge generation layer into the first light-emitting layer of the first light-emitting unit, improving the electron injection capability of the first light-emitting unit. In this way, the overall electron injection capability of the light-emitting device may be improved, thereby improving the light extraction efficiency of the light-emitting device and reducing the driving voltage required by the light-emitting device.

The foregoing descriptions are merely specific implementations of the present disclosure, but the protection scope of the present disclosure is not limited thereto. Changes or replacements that any person skilled in the art could conceive of within the technical scope of the present disclosure shall be included in the protection scope of the present disclosure. Therefore, the protection scope of the present disclosure shall be subject to the protection scope of the claims.

1. A light-emitting device, comprising:
a first electrode, at least two light-emitting units and a second electrode that are stacked in sequence, wherein
the at least two light-emitting units include a first light-emitting unit, and a second light-emitting unit located between the first light-emitting unit and the second electrode, and the light-emitting device further comprises a charge generation layer located between the first light-emitting unit and the second light-emitting unit, wherein
the first light-emitting unit includes a first light-emitting layer; and multiple film layers located on a side of the first light-emitting layer away from the first electrode in the light-emitting device collectively include at least three types of metals.

2. The light-emitting device according to claim 1, wherein in the multiple film layers located on the side of the first light-emitting layer away from the first electrode in the light-emitting device, at least three film layers each include metal.

3. The light-emitting device according to claim 2, wherein the at least three film layers include a first film layer, a second film layer and a third film layer that are arranged in sequence along a direction from the first electrode to the second electrode, wherein
an absolute value of work function of metal in the third film layer is greater than an absolute value of work function of metal in the second film layer, and the absolute value of the work function of the metal in the third film layer is greater than an absolute value of work function of metal in the first film layer.

4. The light-emitting device according to claim 3, wherein the at least three types of metals include first category metal and second category metal, wherein
work function of the first category metal is less than −3.5 eV, and work function of the second category metal is greater than −3.5 eV.

5. The light-emitting device according to claim 4, wherein the work function of the first category metal is in a range of −5.2 eV to −3.5 eV.

6. The light-emitting device according to claim 4, wherein the second light-emitting unit includes a second light-emitting layer; and
in the light-emitting device, at least one type of the second category metal is included in a side of the second light-emitting layer proximate to the first electrode, and at least one type of the first category metal and at least one type of the second category metal are included in a side of the second light-emitting layer away from the first electrode.

7. The light-emitting device according to claim 6, wherein the first film layer is located on the side of the second light-emitting layer proximate to the first electrode, and the second film layer and the third film layer are located on the side of the second light-emitting layer away from the first electrode.

8. The light-emitting device according to claim 7, wherein the second film layer and the third film layer are arranged next to each other.

9. The light-emitting device according to claim 4, wherein in the multiple film layers, a film layer having the first category metal includes at least two types of metals in total.

10. The light-emitting device according to claim 4, wherein at least two film layers located on the side of the first light-emitting layer away from the first electrode in the light-emitting device each include a same type of metal.

11. The light-emitting device according to claim 4, wherein the charge generation layer includes a first charge generation sub-layer and a second charge generation sub-layer, and the first charge generation sub-layer is located between the first light-emitting unit and the second charge generation sub-layer; and
the first charge generation sub-layer includes at least one type of the second category metal.

12. The light-emitting device according to claim 11, wherein a proportion of a volume of the second category metal in the first charge generation sub-layer to a volume of the first charge generation sub-layer is less than or equal to 1%.

13. The light-emitting device according to claim 4, wherein the second electrode includes two types of the first category metal, wherein
a ratio of volumes of the two types of the first category metal is in a range of 100:1 to 1:100.

14. The light-emitting device according to claim 4, wherein in the light-emitting device, a ratio of a total volume of the first category metal to a total volume of the second category metal is less than or equal to 20:1.

15. The light-emitting device according to claim 4, wherein in the light-emitting device, a proportion of a total volume of the second category metal to a total volume of the first category metal and the second category metal is greater than or equal to 5%.

16. The light-emitting device according to claim 4, wherein at least one of the first film layer, the second film layer and the third film layer includes a host material and a doping material including metal, the doping material being doped in the host material.

17. The light-emitting device according to claim 4, wherein at least one of the first film layer, the second film layer and the third film layer includes a first sub-layer, and a second sub-layer located on a side of the first sub-layer, the first sub-layer and/or the second sub-layer including metal.

18. The light-emitting device according to claim 1, wherein at least one type of the at least three types of metals is both a non-alkaline earth metal and a non-alkali metal.

19. The light-emitting device according to claim 18, wherein a proportion of a volume of the metal in the at least three types of metals that is both the non-alkaline earth metal and the non-alkali metal to a volume of the at least three types of metals is greater than or equal to 5%.

20. A display panel, comprising:
a pixel defining layer provided with a plurality of light-emitting openings; and
light-emitting devices located in the light-emitting openings, a light-emitting device of the light-emitting devices being the light-emitting device according to claim 1.
